(19) United States
(12) Patent Application Publication
(10) Pub. No.: US 2025/0318265 A1
(43) Pub. Date: Oct. 9, 2025

(54) DISPLAY DEVICE

(71) Applicant: Samsung Display Co., Ltd., Yongin-Si (KR)

(72) Inventor: Keun Woo KIM, Yongin-si (KR)

(21) Appl. No.: 19/026,768

(22) Filed: Jan. 17, 2025

(30) Foreign Application Priority Data
Apr. 8, 2024 (KR) 10-2024-0047227

(51) Int. Cl. H10D 86/40; H10D 86/60

(52) U.S. Cl. CPC H10D 86/441; H10D 86/423; H10D 86/60

(57) ABSTRACT

The present disclosure relates to a display device capable of improving image quality. According to an embodiment of the disclosure, a display device comprises a light emitting element, a first transistor connected to the light emitting element, a second transistor connected between a data line and the first transistor, a third transistor connected between a gate electrode of the first transistor and a common voltage line, a fourth transistor connected between a driving voltage line and the first transistor, and a capacitor connected between the gate electrode of the first transistor and a drain electrode of the first transistor. At least one of the second transistor or the fourth transistor in the display device may be a field effect transistor, and at least one of the first transistor or the third transistor in the display device may be an oxide semiconductor transistor.

### CROSS-REFERENCE TO RELATED APPLICATION

This application claims priority to and the benefit of Korean Patent Application No. 10-2024-0047227 filed on Apr. 8, 2024, in the Korean Intellectual Property Office under 35 U.S.C. 119, the contents of which in its entirety are herein incorporated by reference.

### BACKGROUND

### 1. Technical Field

The present disclosure relates to a display device capable of improving image quality.

### 2. Description of the Related Art

A head mounted display (HMD) is an image display device that is worn on a user's head in the form of glasses or helmets, with a focal point formed at a close distance in front of the user's eyes. The head mounted display may implement virtual reality (VR) or augmented reality (AR).

The head mounted display magnifies an image displayed on a small display device by using a plurality of lenses, and displays the magnified image. Therefore, the display device applied to the head mounted display needs to provide high-resolution images, for example, images with a resolution of 3000 PPI (Pixels Per Inch) or higher. To this end, an organic light emitting diode on silicon (OLEDoS), which is a small organic light emitting display device with high-resolution, is used as the display device applied to the head mounted display. The OLEDoS is an image display device in which an organic light emitting diode (OLED) is disposed on a semiconductor wafer substrate on which a complementary metal oxide semiconductor (CMOS) is disposed.

### SUMMARY

The present disclosure provides a display device capable of improving image quality.

According to an embodiment of the disclosure, a display device comprises a light emitting element, a first transistor connected to the light emitting element, a second transistor connected between a data line and the first transistor, a third transistor connected between a gate electrode of the first transistor and a common voltage line, a fourth transistor connected between a driving voltage line and the first transistor, and a capacitor connected between the gate electrode of the first transistor and a drain electrode of the first transistor. At least one of the second transistor or the fourth transistor may be a field effect transistor, and at least one of the first transistor or the third transistor may be an oxide semiconductor transistor.

In an embodiment, the field effect transistor may be a P-type transistor.

In an embodiment, the oxide semiconductor transistor may be an N-type transistor.

In an embodiment, the display device may further comprise a substrate on which the first to fourth transistors are disposed, wherein at least one of the first transistor or the third transistor may be disposed farther from the substrate than at least one of the second transistor or the fourth transistor.

In an embodiment, the display device may further comprise a write scan line connected to a gate electrode of the second transistor and receiving a write scan signal, an initialization scan line connected to a gate electrode of the third transistor and receiving an initialization scan signal, and an emission control line connected to a gate electrode of the fourth transistor and receiving an emission control signal.

In an embodiment, in an initialization period, each of the initialization scan signal and the write scan signal may have an active level, the emission control signal may have a non-active level, and a reference voltage may be applied to the data line.

In an embodiment, in a threshold voltage detection period after the initialization period, each of the emission control signal and the write scan signal may have an active level, the initialization scan signal may have a non-active level, and the reference voltage may be applied to the data line.

In an embodiment, in a data write period after the threshold voltage detection period, the write scan signal may have an active level, each of the emission control signal and the initialization scan signal may have a non-active level, and a data voltage may be applied to the data line.

In an embodiment, in an emission period after the data write period, the emission control signal may have an active level, each of the initialization scan signal and the write scan signal may have a non-active level, and the reference voltage may be applied to the data line.

In an embodiment, the field effect transistor may be a metal-oxide-semiconductor field effect transistor (MOSFET).

In an embodiment, the oxide semiconductor transistor may contain indium-gallium-zinc oxide or indium-gallium-zinc-tin oxide.

According to an embodiment of the disclosure, a display device comprises a light emitting element, a first transistor connected to the light emitting element, a second transistor connected between a data line and the first transistor, a third transistor connected between a gate electrode of the first transistor and a drain electrode of the first transistor, a fourth transistor connected between a driving voltage line and the first transistor, a fifth transistor connected between an initialization voltage line and an anode electrode of the light emitting element, a sixth transistor connected between the first transistor and the anode electrode of the light emitting element, a first capacitor connected between a drain electrode of the second transistor and the gate electrode of the first transistor, and a second capacitor connected between the drain electrode of the second transistor and a source electrode of the first transistor. At least one of the second transistor, the fourth transistor, or the sixth transistor may be a field effect transistor, and at least one of the first transistor, the third transistor, or the fifth transistor may be an oxide semiconductor transistor.

In an embodiment, the field effect transistor may be a P-type transistor.

In an embodiment, the oxide semiconductor transistor may be an N-type transistor.

In an embodiment, the display device may further comprise a substrate on which the first to sixth transistors are disposed, wherein at least one of the first transistor, the third transistor, or the fifth transistor may be disposed farther from the substrate than at least one of the second transistor, the fourth transistor, or the sixth transistor.

In an embodiment, the display device may further comprise a write scan line connected to a gate electrode of the second transistor and receiving a write scan signal, a compensation scan line connected to a gate electrode of the third transistor and receiving a compensation scan signal, a first emission control line connected to a gate electrode of the fourth transistor and receiving a first emission control signal, a bias scan line connected to a gate electrode of the fifth transistor and receiving a bias scan signal, and a second emission control line connected to a gate electrode of the sixth transistor and receiving a second emission control signal.

In an embodiment, in an initialization period, each of the write scan signal, the compensation scan signal, the second emission control signal, and the bias scan signal may have an active level, the first emission control signal may have a non-active level, and a reference voltage may be applied to the data line.

In an embodiment, in a threshold voltage detection period after the initialization period, each of the write scan signal, the compensation scan signal, and the first emission control signal may have an active level, each of the bias scan signal and the second emission control signal may have a non-active level, and the reference voltage may be applied to the data line.

In an embodiment, in a data write period after the threshold voltage detection period, the write scan signal may have an active level, each of the compensation scan signal, the first emission control signal, the bias scan signal, and the second emission control signal may have a non-active level, and a data voltage may be applied to the data line.

In an embodiment, in a reset period after the data write period, the bias scan signal may have an active level, each of the write scan signal, the compensation scan signal, the first emission control signal, and the second emission control signal may have a non-active level, and the reference voltage may be applied to the data line.

In an embodiment, in an emission period after the reset period, each of the first emission control signal and the second emission control signal may have an active level, each of the write scan signal, the compensation scan signal, and the bias scan signal may have a non-active level, and the reference voltage may be applied to the data line.

In the display device according to an embodiment, a leakage current of a transistor may be reduced, thereby improving image quality.

The effects of the present disclosure are not limited to those described above and other effects of the present disclosure will be apparent to those skilled in the art from the following descriptions.

### BRIEF DESCRIPTION OF THE DRAWINGS

The above and other features of the present disclosure will become more apparent by describing in detail exemplary embodiments thereof with reference to the attached drawings.

FIG. 1 is an exploded perspective view showing a display device according to an embodiment.

FIG. 2 is a block diagram illustrating a display device according to an embodiment.

FIG. 3 is an equivalent circuit of a first pixel according to an embodiment.

FIG. 4 is a layout illustrating a display panel according to an embodiment.

FIGS. 5 and 6 are layouts illustrating embodiments of a display area of FIG. 4.

FIG. 7 is a cross-sectional view illustrating a display panel taken along a line I1-I1′ of FIG. 5.

FIG. 8 is a diagram illustrating a timing of a reference voltage, a data voltage, an emission control signal, an initialization scan signal, and a write scan signal shown in FIG. 3.

FIG. 9 is a diagram illustrating an operation of the display device of FIG. 3 during an initialization period of FIG. 8.

FIG. 10 is a diagram illustrating an operation of the display device of FIG. 3 during a threshold voltage detection period of FIG. 8.

FIG. 11 is a diagram illustrating an operation of the display device of FIG. 3 during a data write period of FIG. 8.

FIG. 12 is a diagram illustrating an operation of the display device of FIG. 3 during an emission period of FIG. 8.

FIG. 13 is an equivalent circuit illustrating a first pixel according to an embodiment.

FIG. 14 is a diagram illustrating a timing of a reference voltage, a data voltage, a first emission control signal, a second emission control signal, a compensation scan signal, a write scan signal, and a bias scan signal shown in FIG. 13.

FIG. 15 is a diagram illustrating an operation of the display device of FIG. 13 during an initialization period of FIG. 14.

FIG. 16 is a diagram illustrating an operation of the display device of FIG. 13 during a threshold voltage detection period of FIG. 14.

FIG. 17 is a diagram illustrating an operation of the display device of FIG. 13 during a data write period of FIG. 14.

FIG. 18 is a diagram illustrating an operation of the display device of FIG. 13 during a reset period of FIG. 14.

FIG. 19 is a diagram illustrating an operation of the display device of FIG. 13 during an emission period of FIG. 14.

FIG. 20 is a perspective view illustrating a head mounted display according to an embodiment.

FIG. 21 is an exploded perspective view illustrating an example of the head mounted display of FIG. 20.

FIG. 22 is a perspective view illustrating a head mounted display according to an embodiment.

FIG. 23 is a graph illustrating the characteristics of off-leakage currents of a silicon transistor and an oxide transistor depending on temperature.

FIG. 24 is a graph illustrating the characteristics of driving current depending on drain voltages of a silicon transistor and an oxide transistor.

FIG. 25 is a block diagram of an electronic device according to one embodiment.

FIGS. 26, 27 and 28 are schematic diagrams of electronic devices according to various embodiments.

### DETAILED DESCRIPTION OF THE EMBODIMENTS

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are merely provided to ensure the completeness of the present disclosure, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached drawings, the thickness of layers and regions is exaggerated for clarity.

Although the terms “first”, “second”, etc. may be used herein to describe various elements, these elements should not be limited by these terms. These terms may be used to distinguish one element from another element. Thus, a first element discussed below may be termed a second element without departing from the teachings of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Each of the features of the various embodiments of the present disclosure may be partially or entirely combined with each other and technically interwork with each other in various ways. Each embodiment may be implemented independently from each other or may be implemented together in association with each other.

Hereinafter, s embodiments of the present disclosure will be described with reference to the accompanying drawings.

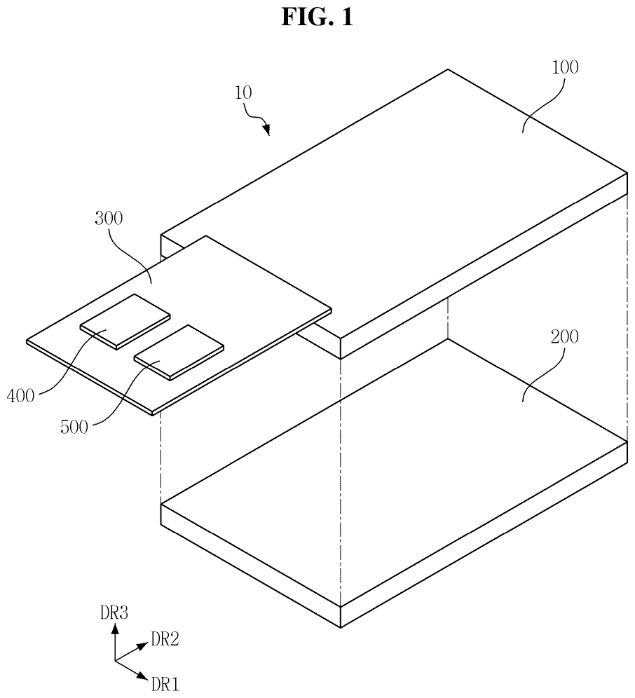

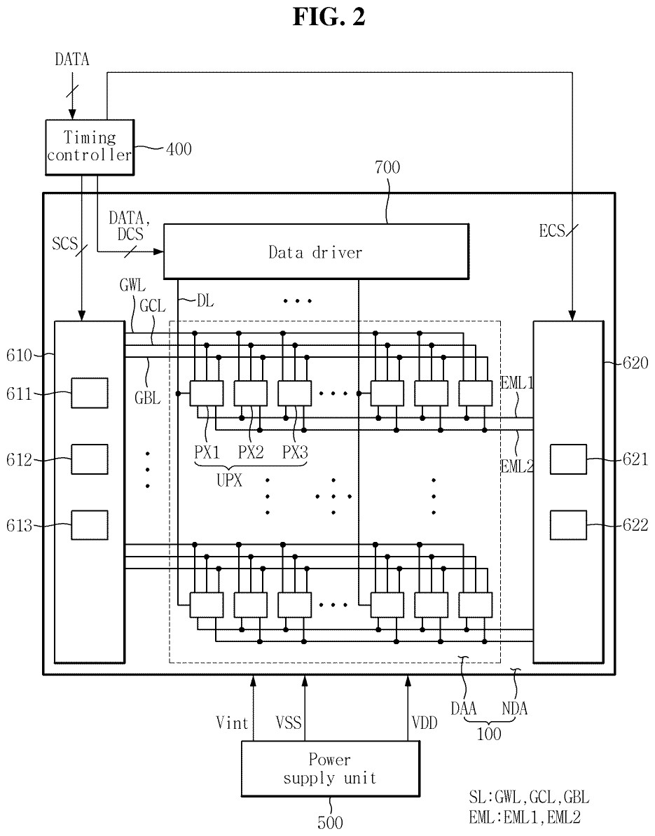

FIG. 1 is an exploded perspective view showing a display device according to an embodiment. FIG. 2 is a block diagram illustrating a display device according to an embodiment.

Referring to FIGS. 1 and 2, a display device 10 according to an embodiment is a device displaying a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to an embodiment may be applied as a display unit of a television, a laptop, a monitor, a billboard, or an Internet-of-Things (IoT) terminal. For example, the display device 10 according to an embodiment may be applied to a smart watch, a watch phone, a head mounted display (HMD) for implementing virtual reality and augmented reality, and the like.

The display device 10 according to an embodiment includes a display panel 100, a heat dissipation layer 200, a circuit board 300, a timing control circuit 400, and a power supply circuit 500.

The display panel 100 may have a planar shape similar to a rectangle. For example, the display panel 100 may have a planar shape similar to a rectangle shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a rectangle shape, and may be a shape similar to another polygonal shape, a circular shape, or an elliptical shape. The planar shape of the display device 10 may conform to the planar shape of the display panel 100, but the embodiment of the present disclosure is not limited thereto.

The display panel 100 includes a display area DAA displaying an image and a non-display area NDA not displaying an image as shown in FIG. 2.

The display area DAA includes a plurality of pixels PX, a plurality of scan lines SL, a plurality of emission control lines EML, and a plurality of data lines DL.

The plurality of pixels PX may be arranged in a matrix form in the first direction DR1 and the second direction DR2. The plurality of scan lines SL and the plurality of emission control lines EML may extend in the first direction DR1, while being arranged in the second direction DR2. The plurality of data lines DL may extend in the second direction DR2, while being arranged in the first direction DR1.

The plurality of scan lines SL includes a plurality of write scan lines GWL, a plurality of compensation scan lines GCL, and a plurality of bias scan lines GBL. The plurality of emission control lines EML includes a plurality of first emission control lines EML1 and a plurality of second emission control lines EML2.

Each of a plurality of unit pixels UPX includes a plurality of pixels PX1, PX2, and PX3. Each of the plurality of pixels PX1, PX2, and PX3 may include a plurality of pixel transistors.

Each of the plurality of pixels PX1, PX2, and PX3 may be connected to any one of the plurality of write scan lines GWL, any one of the plurality of compensation scan lines GCL, any one of the plurality of bias scan lines GBL, any one of the plurality of first emission control lines EML1, any one of the plurality of second emission control lines EML2, and any one of the plurality of data lines DL. Each of the plurality of pixels PX1, PX2, and PX3 may receive a data voltage of the data line DL in response to a write scan signal of the write scan line GWL, and emit light from a light emitting element, which is disposed in each of the plurality of pixels PX1, PX2, and PX3, according to the data voltage.

The non-display area NDA includes a scan driver 610, an emission driver 620, and a data driver 700.

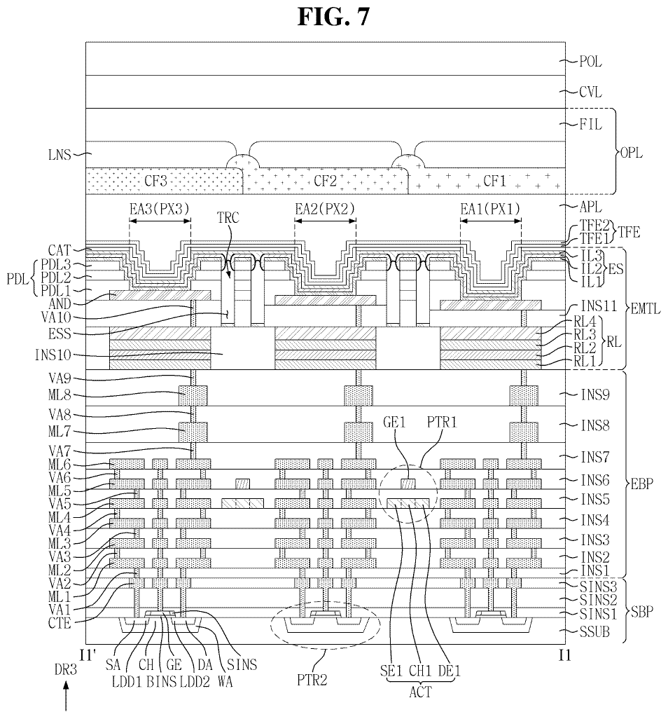

The scan driver 610 includes a plurality of scan transistors, and the emission driver 620 includes a plurality of light emitting transistors. The plurality of scan transistors and the plurality of light emitting transistors may be formed on a semiconductor substrate SSUB (see FIG. 7) through a manufacturing process of a semiconductor. For example, the plurality of scan transistors and the plurality of light emitting transistors may be formed of CMOS. Although it is illustrated in FIG. 2 that the scan driver 610 is disposed on the left side of the display area DAA and the emission driver 620 is disposed on the right side of the display area DAA, the embodiment of the present disclosure is not limited thereto. For example, the scan driver 610 and the emission driver 620 may be disposed on both of the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS from the timing control circuit 400 and output the write scan signals sequentially to the write scan lines GWL. The control scan signal output unit 612 may generate compensation scan signals in response to the scan timing control signal SCS and sequentially output the compensation scan signals to the compensation scan lines GCL. The initialization scan signal output unit 613 may generate initialization scan signals in response to the scan timing control signal SCS and sequentially output the initialization scan signals to the initialization scan lines GIL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EML1. The second emission control driver 622 may generate second emission control signals according to the emission timing control signal ECS and sequentially output the second emission control signals to the second emission control lines EML2.

The data driver 700 may include a plurality of data transistors, and the plurality of data transistors may be formed on the semiconductor substrate SSUB (see FIG. 7) through the manufacturing process of the semiconductor. For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, when the pixels PX1, PX2, and PX3 are selected by the write scan signal of the scan driver 610, data voltages may be supplied to the selected pixels PX1, PX2, and PX3.

The heat dissipation layer 200 may overlap the display panel 100 in a third direction DR3, which is the thickness direction of the display panel 100. The heat dissipation layer 200 may be disposed on a first surface of the display panel 100, for example, on the rear surface thereof. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

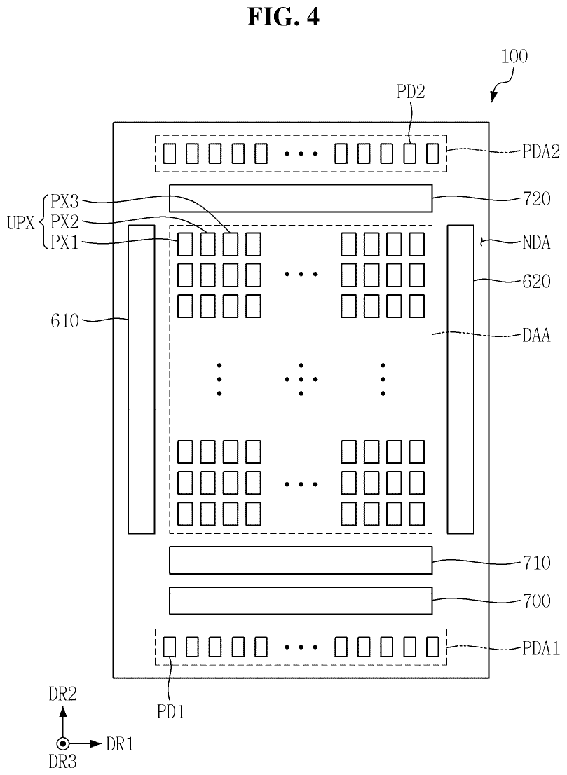

The circuit board 300 may have a first end which is electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, a second end of the circuit board 300 may be disposed on the rear surface of the display panel 100 or the rear surface of the heat dissipation layer 200. The second end of the circuit board 300 may be an opposite side to the first end of the circuit board 300 connected to the plurality of first pads PD1 (see FIG. 4) of the display panel 100 through the conductive adhesive member.

The timing control circuit 400 may receive digital video data and timing signals input from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a common voltage VSS, a driving voltage VDD, and an initialization voltage Vint and supply them to the display panel 100.

Each of the timing control circuit 400 and the power supply circuit 500 may be formed as an integrated circuit (IC) and attached to a first surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the common voltage VSS, the driving voltage VDD, and the initialization voltage Vint of the power supply circuit 500 may be supplied to the display panel 100 through the circuit board 300. However, the embodiment of the present disclosure is not limited thereto.

For example, each of the timing control circuit 400 and the power supply circuit 500 may be disposed on the non-display area NDA of the display panel 100, similar to the scan driver 610, the emission driver 620, and the data driver 700. Each of the timing control circuit 400 and the power supply circuit 500 may include a plurality of timing transistors and a plurality of power transistors, respectively. The plurality of timing transistors and the plurality of power transistors may be formed on the semiconductor substrate SSUB (see FIG. 7) through the manufacturing process of the semiconductor. For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

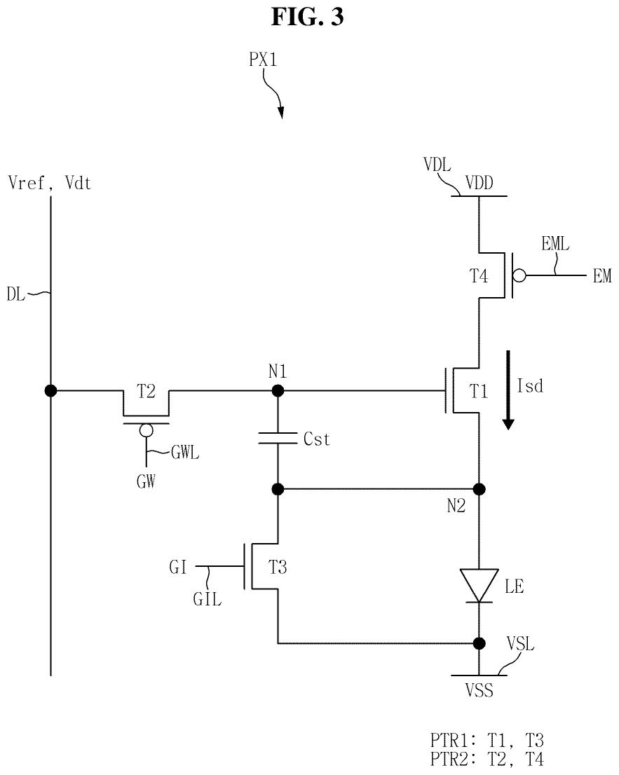

FIG. 3 is an equivalent circuit of a first pixel according to an embodiment.

Referring to FIG. 3, a first pixel PX1 may be connected to the write scan line GWL, the initialization scan line GIL, the emission control line EML, and the data line DL. Further, the first pixel PX1 may be connected to a common voltage line VSL to which the common voltage VSS corresponding to a low potential voltage is applied, and a driving voltage line VDL to which the driving voltage VDD corresponding to a high potential voltage is applied. That is, the common voltage line VSL may be a low potential voltage line and the driving voltage line VDL may be a high potential voltage line. The driving voltage VDD may be a voltage greater than the common voltage VSS.

The first pixel PX1 may include a first pixel transistor PTR1, a second pixel transistor PTR2, a capacitor Cst, and a light emitting element LE. Here, the first pixel transistor PTR1 may include a first transistor T1 and a third transistor T3, and the second pixel transistor PTR2 may include a second transistor T2 and a fourth transistor T4.

The light emitting element LE emits light in response to a driving current Isd flowing through a channel of the first transistor T1. The emission amount of the light emitting element LE may be proportional to the driving current Isd. The light emitting element LE may be connected between a second node N2 and the common voltage line VSL. A first electrode of the light emitting element LE may be connected to the second node N2, and a second electrode thereof may be connected to the common voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment of the present disclosure is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Isd (hereinafter referred to as a “driving current”) flowing between a source electrode and a drain electrode thereof according to a voltage applied to a gate electrode thereof. The first transistor T1 may include the gate electrode connected to a first node N1, the source electrode connected to a drain electrode of the fourth transistor T4, and the drain electrode connected to the second node N2. The first transistor T1 may be an N-type transistor.

The second transistor T2 may be connected between the data line DL and a first electrode of a capacitor Cst. The second transistor T2 may be turned on by a write scan signal GW of the write scan line GWL to connect the data line DL to the first electrode of the capacitor Cst. The second transistor T2 may include a gate electrode connected to the write scan line GWL, a source electrode connected to the data line DL, and a drain electrode connected to the first electrode of the capacitor Cst. The second transistor T2 may be a P-type transistor. A reference voltage Vref and a data voltage Vdt may be applied to the data line DL.

The third transistor T3 may be connected between the second node N2 and the common voltage line VSL. The third transistor T3 may be turned on by an initialization scan signal GI of the initialization scan line GIL to connect the second node N2 to the common voltage line VSL. The third transistor T3 may include a gate electrode connected to the initialization scan line GIL, a drain electrode connected to the second node N2, and a source electrode connected to the common voltage line VSL. The third transistor T3 may be an N-type transistor.

The fourth transistor T4 may be connected between the driving voltage line VDL and the source electrode of the first transistor T1. The fourth transistor T4 may be turned on by an emission control signal EM of the emission control line EML to connect the driving voltage line VDL to the source electrode of the first transistor T1. The fourth transistor T4 may include a gate electrode connected to the emission control line EML, a source electrode connected to the driving voltage line VDL, and the drain electrode connected to the drain electrode of the first transistor T1. The fourth transistor T4 may be a P-type transistor.

The capacitor Cst may be connected between the first node N1 and a second node N2. The first electrode of the capacitor Cst may be connected to the first node N1, and the second electrode of the capacitor Cst may be connected to the second node N2.

At least one of the aforementioned first to fourth transistors T1 to T4 may be a metal-oxide-semiconductor field effect transistor (MOSFET). According to an embodiment, at least one of the first to fourth transistors T1 to T4 may be a silicon-based transistor (e.g., a silicon semiconductor transistor). For example, each of the second transistor T2 and the fourth transistor T4 corresponding to the second pixel transistor PTR2 may be a P-type MOSFET containing a silicon semiconductor (or a silicon semiconductor material).

At least one of the first to fourth transistors T1 to T4 described above may be an oxide-based transistor (e.g., an oxide semiconductor transistor). For example, each of the first transistor T1 and the third transistor T3 corresponding to the first pixel transistor PTR1 may be an N-type oxide-based transistor. In other words, each of the first transistor T1 and the third transistor T3 may include an oxide semiconductor (or an oxide semiconductor material). Since the oxide semiconductor has high carrier mobility and low leakage current, the voltage drop is not significant even when the driving time is long. For example, in the case of an oxide semiconductor, even when low-frequency driving, a color change of an image due to a voltage drop is not large, thus making the low-frequency driving possible. Accordingly, since each of the first transistor T1 and the third transistor T3 includes an oxide semiconductor material, it is possible to implement a display device reducing the power consumption and preventing the generation of leakage current. In addition, when using an oxide semiconductor transistor, a crystallization process by excimer laser annealing (ELA) is not required to form a low-temperature polycrystalline silicon (LTPS) semiconductor transistor, which may reduce the manufacturing cost of the display panel and is advantageous for implementation of a large-area display device.

The oxide semiconductor is sensitive to light, so that a fluctuation in current amount and the like may occur due to light from the outside. Accordingly, it may be considered to place a metal layer under the oxide semiconductor which absorbs or reflects light from the outside. The metal layer positioned under the oxide semiconductor of each of the first transistor T1 and the third transistor T3 may function as a lower gate electrode (e.g., a counter gate electrode). For example, each of the first transistor T1 and the third transistor T3 may be double gate transistors having two gate electrodes (e.g., a gate electrode and a counter gate electrode). The gate electrode and the counter gate electrode may be disposed to face each other on different layers. For example, each of the first transistor T1 and the third transistor T3 is an N-type oxide semiconductor transistor, and the gate electrode and the counter gate electrode of each of the first transistor T1 and the third transistor T3 may be positioned to face each other with an oxide semiconductor interposed therebetween.

Since the first transistor T1 and third transistor T3 include an oxide-based active layer (or semiconductor layer), the leakage current (e.g., leakage current in a turn-on state) of the first transistor T1 and the third transistor T3 may be minimized. Accordingly, voltage fluctuations of the first node N1 to which the gate electrode of the first transistor T1, the drain electrode of the second transistor T2, and the first electrode of the capacitor Cst are commonly connected may be minimized, so that the image quality of the display device 10 may be improved.

Although FIG. 3 illustrates that the first pixel PX1 includes four transistors T1 to T4 and one capacitor Cst, the equivalent circuit of the first pixel PX1 is not limited to an embodiment shown in FIG. 3. For example, the number of the transistors and the number of the capacitors of the first pixel PX1 may be changed in various ways.

In addition, the equivalent circuit of a second pixel PX2 and the equivalent circuit of a third pixel PX3 may be substantially the same as the equivalent circuit of the first pixel PX1 described in conjunction with FIG. 3. Thus, in the present disclosure, description of the equivalent circuit of the second pixel PX2 and the equivalent circuit of the third pixel PX3 will be omitted.

FIG. 4 is a layout illustrating a display panel according to an embodiment.

Referring to FIG. 4, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on a first side of the display area DAA, and the emission driver 620 may be disposed on a second side of the display area DAA. For example, the scan driver 610 may be disposed on a left side of the display area DAA in the first direction DR1, and the emission driver 620 may be disposed on a right other side of the display area DAA in the first direction DR1. However, the embodiment of the present disclosure is not limited thereto, and the scan driver 610 and the emission driver 620 may be disposed on both of the first side and the second side of the display area DAA.

The first pad portion PDA1 may include the plurality of first pads PD1 connected to pads or bumps of the circuit board 300 through the conductive adhesive member. The first pad portion PDA1 may be disposed on a third side of the display area DAA. For example, the first pad portion PDA1 may be disposed on a lower side of the display area DAA in the second direction DR2.

The first pad portion PDA1 may be disposed outside the data driver 700 in the second direction DR2. That is, the first pad portion PDA1 may be disposed closer to a lower edge of the display panel 100 than the data driver 700.

The second pad portion PDA2 may include a plurality of second pads PD2 which is used as inspection pads. The second pad portion PDA2 may be used to test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages, applied through a first pad PD1 of the first pad portion PDA1, to multiple data lines DL. As a result, the number of the plurality of first pads PD1 may be reduced. The first distribution circuit 710 may be disposed on the third side of the display area DAA of the display panel 100. For example, the first distribution circuit 710 may be disposed on the lower side of the display area DAA in the second direction DR2.

The second distribution circuit 720 distributes signals, applied through the second pad portion PDA2, to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on a fourth side of the display area DAA of the display panel 100. For example, the second distribution circuit 720 may be disposed on an upper side of the display area DAA in the second direction DR2.

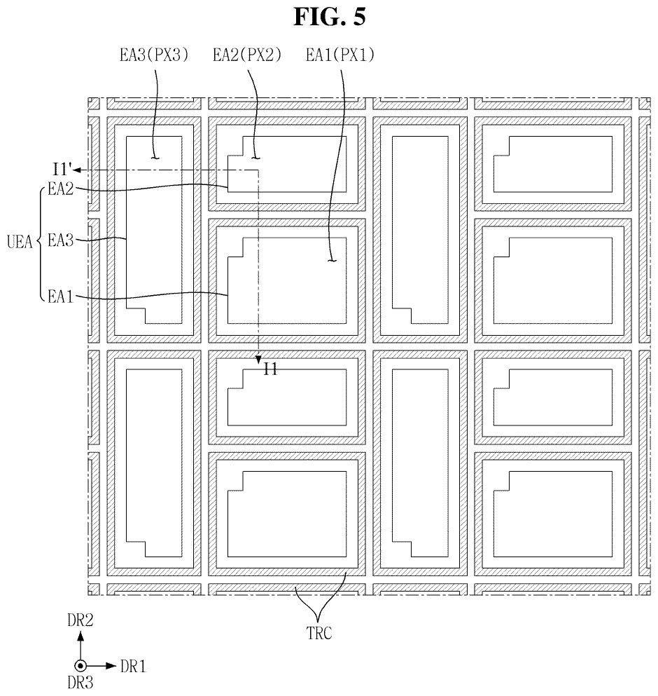

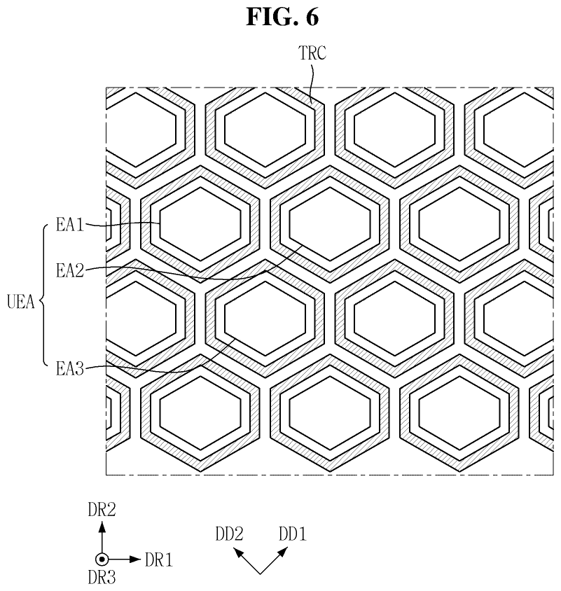

FIGS. 5 and 6 are layouts illustrating embodiments of a display area of FIG. 4.

Referring to FIGS. 5 and 6, each of the plurality of unit pixels UPX includes a first emission area EA1 as an emission area of the first pixel PX1, a second emission area EA2 as an emission area of the second pixel PX2, and a third emission area EA3 as an emission area of the third pixel PX3. In other words, the unit pixel UPX may include a unit emission area UEA, and the unit emission area UEA includes the first emission area EA1, the second emission area EA2, and the third emission area EA3 described above.

Referring to FIGS. 5 and 6, each of the plurality of pixels PX includes the first emission area EA1 as an emission area of the first pixel PX1, the second emission area EA2 as an emission area of the second pixel PX2, and the third emission area EA3 as an emission area of the third pixel PX3.

Each of the first emission area EA1, the second emission area EA2, and the third emission area EA3 may have a polygonal, circular, elliptical, or atypical shape in a plan view.

The maximum length of the third emission area EA3 in the first direction DR1 may be smaller than the maximum length of the second emission area EA2 in the first direction DR1 and the maximum length of the first emission area EA1 in the first direction DR1. The maximum length of the second emission area EA2 in the first direction DR1 and the maximum length of the first emission area EA1 in the first direction DR1 may be substantially the same.

The maximum length of the third emission area EA3 in the second direction DR2 may be greater than the maximum length of the second emission area EA2 in the second direction DR2 and the maximum length of the first emission area EA1 in the second direction DR2. The maximum length of the second emission area EA2 in the second direction DR2 may be smaller than the maximum length of the first emission area EA1 in the second direction DR2. The maximum length of the third emission area EA3 in the second direction DR2 may be greater than the maximum length of the second emission area EA2 in the second direction DR2.

The first emission area EA1, the second emission area EA2, and the third emission area EA3 may have, in the plan view, a rectangular shape or a hexagonal shape as shown in FIGS. 5 and 6, but the embodiment of the present disclosure is not limited thereto. The first emission area EA1, the second emission area EA2, and the third emission area EA3 may have a polygonal shape other than a rectangle or a hexagon, such as a circular shape, an elliptical shape, or an atypical shape in the plan view.

As shown in FIG. 5, in each of the plurality of pixels PX, the third emission area EA3 and the second emission area EA2 may be adjacent to each other in the first direction DR1. Further, the third emission area EA3 and the first emission area EA1 may be adjacent to each other in the first direction DR1. In addition, the first emission area EA1 and the second emission area EA2 may be adjacent to each other in the second direction DR2. The area of the first emission area EA1, the area of the second emission area EA2, and the area of the third emission area EA3 may be different. However, the present disclosure is not limited thereto.

As shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

In FIGS. 5 and 6, each of the plurality of pixels PX includes three emission areas EA1, EA2, and EA3, but the embodiment of the present disclosure is not limited thereto. That is, each of the plurality of pixels PX may include four emission areas.

In addition, the layout of the emission areas of the plurality of pixels PX is not limited to those illustrated in FIGS. 5 and 6. For example, the emission areas of the plurality of pixels PX may be disposed in a stripe structure in which the emission areas are arranged in the first direction DR1, a PenTile® structure in which the emission areas are arranged in a diamond shape, or a hexagonal structure in which the emission areas having, in the plan view, a hexagonal shape are arranged side by side as shown in FIG. 6.

FIG. 7 is a cross-sectional view illustrating a display panel taken along a line I1-I1′ of FIG. 5.

Referring to FIG. 7, the display panel 100 includes a semiconductor backplane SBP, a light emitting element backplane EBP, a display element layer EMTL, an encapsulation layer TFE, an optical layer OPL, a cover layer CVL, and a polarizing plate POL.

The semiconductor backplane SBP includes the semiconductor substrate SSUB including a plurality of second pixel transistors PTR2, a plurality of semiconductor insulating layers covering the plurality of second pixel transistors PTR2, and a plurality of contact terminals CTE electrically connected to the plurality of second pixel transistors PTR2, respectively. The plurality of second pixel transistors PTR2 may include at least one of the second transistor T2 and the fourth transistor T4 described in conjunction with FIG. 3. For example, one of the plurality of second pixel transistors PTR2 may be the second transistor T2, and another one may be the fourth transistor T4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity included in the semiconductor substrate SSUB. For example, if the first type impurity is a p-type impurity, the second type impurity may be an n-type impurity. If the first type impurity is an n-type impurity, the second type impurity may be a p-type impurity.

Each of the plurality of well regions WA includes a source region SA corresponding to the source electrode of the second pixel transistor PTR2, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on a side surface of the gate electrode GE. The side insulating layer SINS may be disposed on the lower insulating layer BINS.

Each of the source region SA and the drain region DA may be a region doped with the second type impurity. The gate electrode GE of the second pixel transistor PTR2 may overlap the well region WA in the third direction DR3. The channel region CH may overlap the gate electrode GE in the third direction DR3. The source region SA may be disposed on one side of the gate electrode GE, and the drain region SA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the presence of the first low-concentration impurity region LDD1 and the second low-concentration impurity region LDD2. As the length of the channel region CH in each of the second pixel transistors PTR2 may be increased, punch-through and hot carrier phenomena that might be caused by a short channel may be prevented.

A first semiconductor insulating layer SINS1 may be disposed on the semiconductor substrate SSUB. The first semiconductor insulating layer SINS1 may be formed of silicon carbonitride (SiCN) or a silicon oxide (SiOx)-based inorganic layer, but the embodiment of the present disclosure is not limited thereto.

A second semiconductor insulating layer SINS2 may be disposed on the first semiconductor insulating layer SINS1. The second semiconductor insulating layer SINS2 may be formed of a silicon oxide (SiOx)-based inorganic layer, but the embodiment of the present disclosure is not limited thereto.

The plurality of contact terminals CTE may be disposed on the second semiconductor insulating layer SINS2. Each of the plurality of contact terminals CTE may be connected to any one of the gate electrode GE, the source region SA, and the drain region DA of each of the second pixel transistors PTR2 through contact holes extending through the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be disposed on a side surface of each of the plurality of contact terminals CTE. The top surface of each of the plurality of contact terminals CTE may not be covered by the third semiconductor insulating layer SINS3. The third semiconductor insulating layer SINS3 may be formed of a silicon oxide (SiOx)-based inorganic layer, but the embodiment of the present disclosure is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of insulating layers INS1 to INS9. In addition, the light emitting element backplane EBP includes a plurality of insulating layers INS1 to INS11 disposed between the first to eighth conductive layers ML1 to ML8.

The first to eighth conductive layers ML1 to ML8 serve to connect the plurality of contact terminals CTE disposed on an upper surface of the semiconductor backplane SBP to implement the circuit of the first pixel PX1 shown in FIG. 3. For example, as the second and fourth transistors T2 and T4 may be formed in the semiconductor backplane SBP, the connection between the first to fourth transistors T1 to T4 and the capacitor Cst may be made through the first to eighth conductive layers ML1 to ML8.

A first insulating layer INS1 may be disposed on the semiconductor backplane SBP. Each of first vias VA1 may extend through the first insulating layer INS1 to be connected to the contact terminal CTE disposed on the upper surface of the semiconductor backplane SBP. Each of first conductive layers ML1 may be disposed on the first insulating layer INS1 and may be connected to the first via VA1.

A second insulating layer INS2 may be disposed on the first insulating layer INS1 and the first conductive layers ML1. Each of second vias VA2 may extend through the second insulating layer INS2 and be connected to the first conductive layer ML1. Each of second conductive layers ML2 may be disposed on the second insulating layer INS2 and may be connected to the second via VA2.

A third insulating layer INS3 may be disposed on the second insulating layer INS2 and the second conductive layers ML2. Each of third vias VA3 may extend through the third insulating layer INS3 and be connected to the second conductive layer ML2. Each of third conductive layers ML3 may be disposed on the third insulating layer INS3 and may be connected to the third via VA3.

A fourth insulating layer INS4 may be disposed on the third insulating layer INS3 and the third conductive layers ML3. Each of fourth vias VA4 may extend through the fourth insulating layer INS4 and be connected to the third conductive layer ML3. Each of fourth conductive layers ML4 may be disposed on the fourth insulating layer INS4 and may be connected to the fourth via VA4.

A fifth insulating layer INS5 may be disposed on the fourth insulating layer INS4 and the fourth conductive layers ML4. Each of fifth vias VA5 may extend through the fifth insulating layer INS5 and be connected to the fourth conductive layer ML4. Each of fifth conductive layers ML5 may be disposed on the fifth insulating layer INS5 and may be connected to the fifth via VA5.

A sixth insulating layer INS6 may be disposed on the fifth insulating layer INS5 and the fifth conductive layers ML5. Each of sixth vias VA6 may extend through the sixth insulating layer INS6 and be connected to the fifth conductive layer ML5. Each of sixth conductive layers ML6 may be disposed on the sixth insulating layer INS6 and may be connected to the sixth via VA6.

A seventh insulating layer INS7 may be disposed on the sixth insulating layer INS6 and the sixth conductive layers ML6. Each of seventh vias VA7 may extend through the seventh insulating layer INS7 and be connected to the sixth conductive layer ML6. Each of seventh conductive layers ML7 may be disposed on the seventh insulating layer INS7 and may be connected to the seventh via VA7.

An eighth insulating layer INS8 may be disposed on the seventh insulating layer INS7 and the seventh conductive layers ML7. Each of eighth vias VA8 may extend through the eighth insulating layer INS8 and be connected to the seventh conductive layer ML7. Each of eighth conductive layers ML8 may be disposed on the eighth insulating layer INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating layers INS1 to INS8 may be formed of a silicon oxide (SiOx)-based inorganic layer, but the embodiment of the present disclosure is not limited thereto.

The thicknesses of each of the first conductive layer ML1, the second conductive layer ML2, the third conductive layer ML3, the fourth conductive layer ML4, the fifth conductive layer ML5, and the sixth conductive layer ML6 may be greater than the thicknesses of each of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of each of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å, and the thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating layer INS9 may be disposed on the eighth insulating layer INS8 and the eighth conductive layer ML8. The ninth insulating layer INS9 may be formed of a silicon oxide (SiOx)-based inorganic layer, but the embodiment of the present disclosure is not limited thereto.

Each of ninth vias VA9 may extend through the ninth insulating layer INS9 and be connected to the eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16500 Å.

The display element layer EMTL may be disposed on the light emitting element backplane EBP. The display element layer EMTL may include the light emitting elements LE each including a reflective electrode layer RL, tenth and eleventh insulating layers INS10 and INS11, a tenth via VA10, a first electrode AND, a light emitting stack ES, a second electrode CAT, a pixel defining film PDL, and a plurality of trenches TRC.

The reflective electrode layer RL may be disposed on the ninth insulating layer INS9. The reflective electrode layer RL may include at least one reflective electrode RL1, RL2, RL3, and RLA. For example, the reflective electrode layer RL may include first to fourth reflective electrodes RL1, RL2, RL3, and RL4 as shown in FIG. 7.

Each of the first reflective electrodes RL1 may be disposed on the ninth insulating layer INS9, and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

Each of the fourth reflective electrodes RL4 may be disposed on the third reflective electrodes RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RLA. For example, the thickness of each of the first reflective electrode RL1, the third reflective electrode RL3, and the fourth reflective electrode RL4 may be approximately 100 Å, and the thickness of the second reflective electrode RL2 may be 850 Å.

The tenth insulating layer INS10 may be disposed on the ninth insulating layer INS9. The tenth insulating layer INS10 may be disposed between the reflective electrode layers RL adjacent to each other in a horizontal direction. The tenth insulating layer INS10 may be disposed on the reflective electrode layer RL in the third pixel PX3. The tenth insulating layer INS10 may be formed of a silicon oxide (SiOx)-based inorganic layer, but the embodiment of the present disclosure is not limited thereto.

The eleventh insulating layer INS11 may be disposed on the tenth insulating layer INS10 and the reflective electrode layer RL. The eleventh insulating layer INS11 may be formed of a silicon oxide (SiOx)-based inorganic layer, but the embodiment of the present disclosure is not limited thereto. The tenth insulating layer INS10 and the eleventh insulating layer INS11 may be an optical auxiliary layer through which light reflected by the reflective electrode layer RL passes, among light emitted from the light emitting elements LE.

In order to match the resonance distance of the light emitted from the light emitting elements LE in at least one of the first pixel PX1, the second pixel PX2, or the third pixel PX3, the tenth insulating layer INS10 and the eleventh insulating layer INS11 may not be disposed under the first electrode AND of the first pixel PX1. The first electrode AND of the first pixel PX1 may be directly disposed on the reflective electrode layer RL. The eleventh insulating layer INS11 may be disposed under the first electrode AND of the second pixel PX2. The tenth insulating layer INS10 and the eleventh insulating layer INS11 may be disposed under the first electrode AND of the third pixel PX3. However, the present disclosure is not limited thereto. For example, the eleventh insulating layer INS11 may be disposed under the first electrode AND of the first pixel PX1, the first electrode AND of the second pixel PX2, and the first electrode AND of the third pixel PX3. In this case, the thickness of the eleventh insulating layer INS11 disposed under the first electrode AND of the first pixel PX1 is smaller than the thickness of the eleventh insulating layer INS11 disposed under the first electrode AND of the second pixel PX2. And the thickness of the eleventh insulating layer INS11 disposed under the first electrode AND of the second pixel PX2 is smaller than the thickness of the eleventh insulating layer INS11 disposed under the first electrode AND of the third pixel PX3

In summary, the distance between the first electrode AND and the reflective electrode layer RL may be different in the first pixel PX1, the second pixel PX2, and the third pixel PX3. In order to adjust the distance from the reflective electrode layer RL to the second electrode CAT according to the main wavelength of the light emitted from each of the first pixel PX1, the second pixel PX2, and the third pixel PX3, the presence or absence of the tenth insulating layer INS10 and the eleventh insulating layer INS11 may be set in each of the first pixel PX1, the second pixel PX2, and the third pixel PX3. For example, it is illustrated in FIG. 7 that the distance between the first electrode AND and the reflective electrode layer RL in the third pixel PX3 is greater than the distance between the first electrode AND and the reflective electrode layer RL in the second pixel PX2 and the distance between the first electrode AND and the reflective electrode layer RL in the first pixel PX1. The distance between the first electrode AND and the reflective electrode layer RL in the second pixel PX2 is greater than the distance between the first electrode AND and the reflective electrode layer RL in the first pixel PX1. However, the embodiment of the present disclosure is not limited thereto.

In addition, although the tenth insulating layer INS10 and the eleventh insulating layer INS11 are illustrated in the embodiment of the present disclosure, a twelfth insulating layer disposed under the first electrode AND of the first pixel PX1 may be added. In this case, the eleventh insulating layer INS11 and a twelfth insulating layer INS12 may be disposed under the first electrode AND of the second pixel PX2, and the tenth insulating layer INS10, the eleventh insulating layer INS11, and the twelfth insulating layer INS12 may be disposed under the first electrode AND of the third pixel PX3.

Each of the tenth vias VA10 may extend through the tenth insulating layer INS10 and/or the eleventh insulating layer INS11 in the second pixel PX2 and the third pixel PX3 and may be connected to the reflective electrode layer RL. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second pixel PX2 may be smaller than the thickness of the tenth via VA10 in the third pixel PX3.

The first electrode AND of each of the light emitting elements LE may be disposed on the tenth insulating layer INS10 and connected to the tenth via VA10. The first electrode AND of each of the light emitting elements LE may be connected to the drain region DA or source region SA of the second pixel transistor PTR2 through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may serve to partition the first emission areas EA1, the second emission areas EA2, and the third emission areas EA3.

The first emission area EA1 may be defined as an area in which the first electrode AND, the light emitting stack ES, and the second electrode CAT are sequentially stacked in the first pixel PX1 to emit light. The second emission area EA2 may be defined as an area in which the first electrode AND, the light emitting stack ES, and the second electrode CAT are sequentially stacked in the second pixel PX2 to emit light. The third emission area EA3 may be defined as an area in which the first electrode AND, the light emitting stack ES, and the second electrode CAT are sequentially stacked in the third pixel PX3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the embodiment of the present disclosure is not limited thereto. Each of the first pixel defining film PDL1, the second pixel defining film PDL2, and the third pixel defining film PDL3 may have a thickness of about 500 Å.

When the first pixel defining film PDL1, the second pixel defining film PDL2, and the third pixel defining film PDL3 are formed as one pixel defining film, the height of the pixel defining film formed in a single layer increases, which may cause a first encapsulation inorganic film TFE1 to break due to step coverage. Step coverage refers to the ratio between the degree of thin film coated on an inclined portion and the degree of thin film coated on a flat portion. The lower the step coverage, the more likely the thin film will be cut off at inclined portions.

Therefore, in order to prevent the first encapsulation inorganic film TFE1 from breaking due to the step coverage, the first pixel defining film PDL1, the second pixel defining film PDL2, and the third pixel defining film PDL3 may have a cross-sectional structure having a stepped portion. For example, a width of the first pixel defining film PDL1 may be greater than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1.

Each of the plurality of trenches TRC may extend through the first pixel defining film PDL1, the second pixel defining film PDL2, and the third pixel defining film PDL3. Furthermore, each of the plurality of trenches TRC may extend through the eleventh insulating layer INS11. The tenth insulating layer INS10 may be partially recessed at each of the plurality of trenches TRC.

At least one trench TRC may be disposed between two adjacent pixels among PX1, PX2, and PX3. Although FIG. 7 illustrates that two trenches TRC are disposed between adjacent two pixels, the embodiment of the present disclosure is not limited thereto.

The light emitting stack ES may include a plurality of stacked layers. FIG. 7 illustrates that the light emitting stack ES has a three-tandem structure including a first stack layer IL1, a second stack layer IL2, and a third stack layer IL3, but the embodiment of the present disclosure is not limited thereto. For example, the light emitting stack ES may have a two-tandem structure including two intermediate layers.

In the three-tandem structure, the light emitting stack ES may have a tandem structure including a plurality of stack layers IL1, IL2, and IL3 that emit different lights. For example, the light emitting stack ES may include the first stack layer IL1 that emits light of the first color, the second stack layer IL2 that emits light of the second color, and the third stack layer IL3 that emits light of the third color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the second color, and a second electron transport layer are sequentially stacked. The third stack layer IL3 may have a structure in which a third hole transport layer, a third organic light emitting layer that emits light of the third color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be separated between two adjacent pixels PX1, PX2, and PX3. The second stack layer IL2 may be disposed on the first stack layer IL1. Due to the trench TRC, the second stack layer IL2 may be separated between two adjacent pixels PX1, PX2, and PX3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. That is, in the three-tandem structure, each of the plurality of trenches TRC may be a structure which separates the first to second stack layers IL1 and IL2, the first charge generation layer, and the second charge generation layer of the display element layer EMTL between the two adjacent pixels. In addition, in the two-tandem structure, each of the trenches TRC may be a structure cutting off the charge generation layer disposed between a lower intermediate layer and an upper intermediate layer, and the lower intermediate layer.

In order to stably separate the first and second stack layers IL1 and IL2 of the display element layer EMTL between the two adjacent pixels PX1, PX2, and PX3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the first to third stack layers IL1, IL2, and IL3 of the display element layer EMTL between the two adjacent pixels PX1, PX2, and PX3, a different structure may exist instead of the trench TRC. For example, instead of the trench TRC, a reverse tapered partition wall may be disposed on the pixel defining film PDL.

The number of the stack layers IL1, IL2, and IL3 that emit different lights is not limited to those shown in FIG. 7. For example, the light emitting stack ES may include two intermediate layers. In this case, one of the two intermediate layers may be substantially the same as the first stack layer IL1, and the other may include a second hole transport layer, a second organic light emitting layer, a third organic light emitting layer, and a second electron transport layer. In this case, a charge generation layer for supplying electrons to one intermediate layer and supplying charges to the other intermediate layer may be disposed between the two intermediate layers.

In addition, FIG. 7 illustrates that each of the first to third stack layers IL1, IL2, and IL3 is disposed in the first emission area EA1, the second emission area EA2, and the third emission area EA3, but the embodiment of the present disclosure is not limited thereto. For example, the first stack layer IL1 may be disposed in the first emission area EA1, and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third pixels PX1, PX2, and PX3 due to a micro-cavity effect.

The encapsulation layer TFE may be disposed on the display element layer EMTL. The encapsulation layer TFE may include at least one inorganic film TFE1 and TFE2 to prevent oxygen or moisture from permeating into the display element layer EMTL. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) or aluminum oxide (AlOx), but an embodiment of the present disclosure is not limited thereto. The second encapsulation inorganic film TFE2 may be formed by an atomic layer deposition (ALD) process. The thickness of the second encapsulation inorganic film TFE2 may be smaller than the thickness of the first encapsulation inorganic film TFE1.

An organic film APL may be a layer for increasing the interfacial adhesion between the encapsulation layer TFE and the optical layer OPL, and be disposed on the second encapsulation inorganic film TFE2. The organic film APL may be an organic film such as acrylic resin, epoxy resin, phenolic resin, polyamide resin, or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the organic film APL.

The first color filter CF1 may overlap the first emission area EA1 of the first pixel PX1. The first color filter CF1 may transmit light of the first color, i.e., light of a blue wavelength band. The blue wavelength band may be approximately 370 nm to 460 nm. Thus, the first color filter CF1 may transmit light of the first color among light emitted from the first emission area EA1.

The second color filter CF2 may overlap the second emission area EA2 of the second pixel PX2. The second color filter CF2 may transmit light of the second color, i.e., light of a green wavelength band. The green wavelength band may be approximately 480 nm to 560 nm. Thus, the second color filter CF2 may transmit light of the second color among light emitted from the second emission area EA2.

The third color filter CF3 may overlap the third emission area EA3 of the third pixel PX3. The third color filter CF3 may transmit light of the third color, i.e., light of a red wavelength band. The red wavelength band may be approximately 600 nm to 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure designed to increase a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index to make light proceed in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on a first surface of the cover layer CVL, e.g., an upper surface of the cover layer CVL. The polarizing plate POL may be a structure which prevents the degradation of visibility caused by reflection of external light. The polarizing plate POL may include a linear polarizing plate and a phase retardation film. For example, the phase retardation film may be a λ/4 plate (quarter-wave plate), but the embodiment of the present disclosure is not limited thereto. However, when visibility degradation caused by reflection of external light is sufficiently overcome by the first to third color filters CF1, CF2, and CF3, the polarizing plate POL may be omitted.

The first pixel transistor PTR1 may be disposed above the second pixel transistor PTR2. For example, the second pixel transistor PTR2 may be disposed in the semiconductor backplane SBP, and the first pixel transistor PTR1 may be disposed in the light emitting element backplane EBP located above the semiconductor backplane SBP in the third direction DR3. For example, the first pixel transistor PTR1 may include an active layer ACT and a gate electrode GE1 which are disposed in the light emitting element backplane EBP and overlap with each other in the third direction DR3. The active layer ACT of the first pixel transistor PTR1 may be disposed on, e.g., the fourth insulating layer INS4 of the light emitting element backplane EBP, and the gate electrode GE1 of the first pixel transistor PTR1 may be disposed on, e.g., the fifth insulating layer INS5 of the light emitting element backplane EBP. The active layer ACT may include a source electrode SE1, a drain electrode DE1 and a channel region CH1 disposed between the source electrode SE1 and the drain electrode, and the channel region CH1 may overlap the gate electrode GE1. The gate electrode GE1, the source electrode SE1, and the drain electrode DE1 of the first pixel transistor PTR1 may be connected to the second pixel transistor PTR2 through at least one of the first to eighth conductive layers ML1 to ML8.

The active layer ACT of the first pixel transistor PTR1 may include oxide. For example, the active layer ACT of the first pixel transistor PTR1 may be a semiconductor layer including indium-gallium-zinc oxide (IGZO) or indium-gallium-zinc-tin oxide (IGZTO).

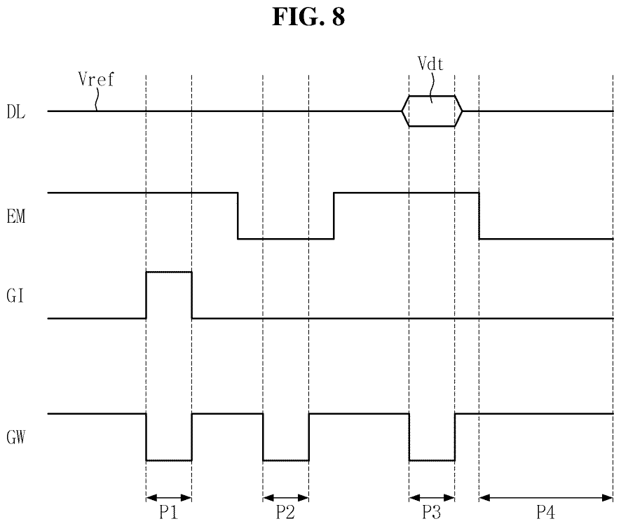

FIG. 8 is a diagram illustrating a timing of the reference voltage Vref, the data voltage Vdt, the emission control signal EM, the initialization scan signal GI, and the write scan signal GW shown in FIG. 3.

The first pixel PX1 may be driven separately for each of an initialization period P1, a threshold voltage detection period P2, a data write period P3, and an emission period P4.

The emission control signal EM, the initialization scan signal GI, and the write scan signal GW may have an active level or a non-active level for each of the above-mentioned periods P1, P2, P3, and P4. Here, the active level of each signal EM, GI, GW described above may mean a voltage level capable of turning on a corresponding transistor to which the corresponding signal is applied. In other words, the active level signal may have a value greater than the threshold voltage of the corresponding transistor. For example, as shown in FIG. 3, when each of the second transistor T2 and the fourth transistor T4 is a P-type transistor, the active level of each of the write scan signal GW and the emission control signal EM may mean a low level (e.g., a negative polarity level or a low voltage level). For example, when the third transistor T3 is an N-type transistor, the active level of the initialization scan signal GI may mean a high level (e.g., a positive polarity level or a high voltage level).

The non-active level of each signal EM, GI, GW may mean a voltage level which turns off a corresponding transistor. In other words, the non-active level signal may have a smaller value than the threshold voltage of the corresponding transistor. For example, as shown in FIG. 3, when each of the second transistor T2 and the fourth transistor T4 is a P-type transistor, the non-active level of each of the write scan signal GW and the emission control signal EM may mean a high level (e.g., a positive polarity level or a high voltage level). For example, when the third transistor T3 is an N-type transistor, the non-active level of the initialization scan signal GI may mean a low level (e.g., a negative polarity level or a low voltage level).

In the initialization period P1, the initialization scan signal GI and the write scan signal GW may each have an active level, while the emission control signal EM may have a non-active level. Further, in the initialization period P1, the reference voltage Vref may be applied to the data line DL.

In the threshold voltage detection period P2, each of the emission control signal EM and the write scan signal GW may have an active level, while the initialization scan signal GI may have a non-active level. Further, in the threshold voltage detection period P2, the reference voltage Vref may be applied to the data line DL.

In the data write period P3, the write scan signal GW may have an active level, while each of the emission control signal EM and the initialization scan signal GI may have a non-active level. Further, in the data write period P3, the data voltage Vdt may be applied to the data line DL.

In the emission period P4, the emission control signal EM may have an active level, while each of the initialization scan signal GI and the write scan signal GW may have a non-active level. Further, in the emission period P4, the reference voltage Vref may be applied to the data line DL.

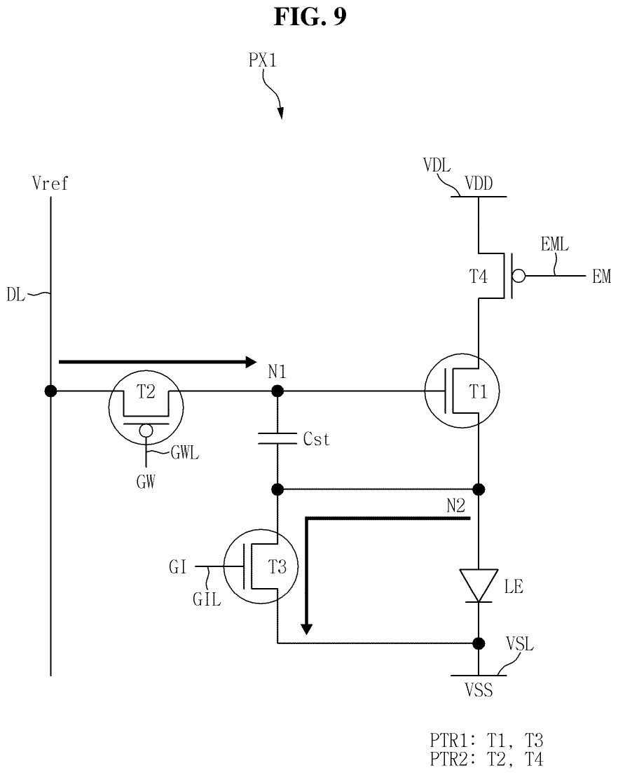

Hereinafter, the operation of the display device 10 will be described with reference to FIGS. 8 to 12 as follows. In FIGS. 9 to 12, the transistor surrounded by a circle means a turned-on transistor.

First, the operation of the display device 10 in the initialization period P1 will be described with reference to FIGS. 8 and 9.

FIG. 9 is a diagram illustrating an operation of the display device 10 of FIG. 3 during an initialization period P1 of FIG. 8.

In the initialization period P1, the write scan signal GW having the active level may be applied to the gate electrode of the second transistor T2 through the write scan line GWL. Accordingly, in the initialization period P1, the second transistor T2 may be turned on.

In the initialization period P1, the initialization scan signal GI having the active level may be applied to the gate electrode of the third transistor T3 through the initialization scan line GIL. Accordingly, in the initialization period P1, the third transistor T3 may be turned on.

In the initialization period P1, the emission control signal EM having the non-active level may be applied to the gate electrode of the fourth transistor T4 through the emission control line EML. Accordingly, in the initialization period P1, the fourth transistor T4 may be turned off.

In the initialization period P1, the reference voltage Vref from the data line DL may be applied to the first node N1 through the turned-on second transistor T2, and the common voltage VSS from the common voltage line VSL may be applied to the second node N2 through the turned-on third transistor T3. Accordingly, the voltages of each of the gate electrode and the drain electrode of the first transistor T1 may be initialized, the voltages of each of the first electrode and the second electrode of the capacitor Cst may be initialized, and the voltage of the anode electrode of the light emitting element LE may be initialized.

In the initialization period P1, the first transistor T1 may be turned on by the reference voltage Vref applied to the first node N1 and the common voltage VSS of the second node N2. Through the turned-on first transistor T1, the common voltage VSS from the common voltage line VSL may be applied to the source electrode of the first transistor T1. Accordingly, in the initialization period P1, the voltage of the source electrode of the first transistor T1 may be initialized.

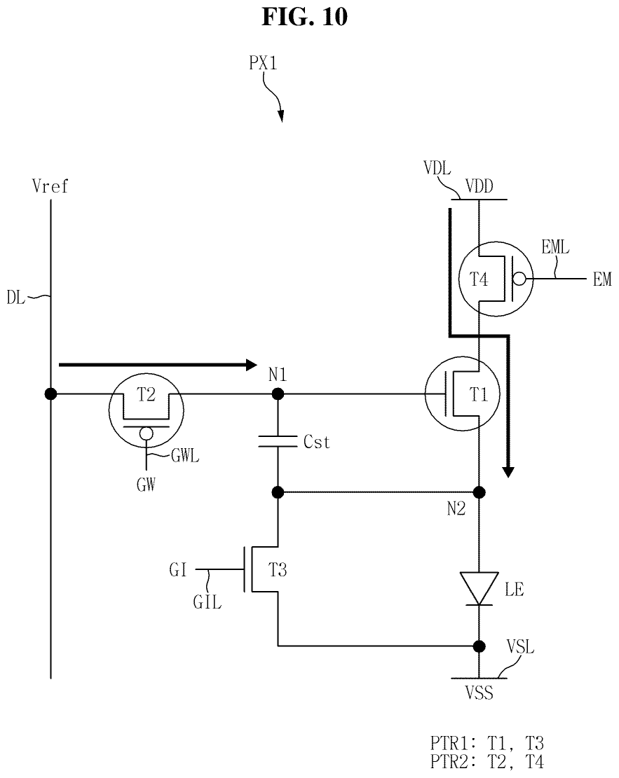

The operation of the display device 10 in the threshold voltage detection period P2 will be described with reference to FIGS. 8 and 10 as follows.

FIG. 10 is a diagram illustrating an operation of the display device 10 of FIG. 3 during a threshold voltage detection period P2 of FIG. 8.

In the threshold voltage detection period P2, the write scan signal GW having the active level may be applied to the gate electrode of the second transistor T2 through the write scan line GWL. Accordingly, in the threshold voltage detection period P2, the second transistor T2 may be turned on.

In the threshold voltage detection period P2, the emission control signal EM having the active level may be applied to the gate electrode of the fourth transistor T4 through the emission control line EML. Accordingly, in the threshold voltage detection period P2, the fourth transistor T4 may be turned on.

In the threshold voltage detection period P2, the initialization scan signal GI of the non-active level may be applied to the gate electrode of the third transistor T3 through the initialization scan line GIL. Accordingly, in the threshold voltage detection period P2, the third transistor T3 may be turned off.

In the threshold voltage detection period P2, the first transistor T1 may be maintained in a turn-on state by the reference voltage Vref applied to the first node N1 and the common voltage VSS applied to the second node N2 in the previous period (e.g., the initialization period P1).

In the threshold voltage detection period P2, the voltage at the second node N2 may be gradually increased by a current flowing through the turned-on first transistor T1. In other words, as the third transistor T3 is turned off, the supply of the common voltage VSS to the second node N2 may be stopped, and accordingly, the voltage at the second node N2 may be gradually increased by a current flowing from the driving voltage line VDL through the turned-on first transistor T1. Accordingly, a voltage (hereinafter, a gate-drain voltage) between the gate electrode and the drain electrode of the first transistor T1 may be gradually decreased, and when the gate-drain voltage reaches the threshold voltage of the first transistor T1, the first transistor T1 may be turned off. At this time, a threshold voltage of the first transistor T1 may be detected and the detected threshold voltage of the first transistor T1 may be reflected in the second node N2. For example, when the first transistor T1 is turned off during the threshold voltage detection period P2, the voltage at the second node N2 may have a value corresponding to “Vref-Vth.” “Vth” means the threshold voltage of the first transistor T1. The threshold voltage of the first transistor T1 reflected in the second node N2 may be maintained by the capacitor Cst.

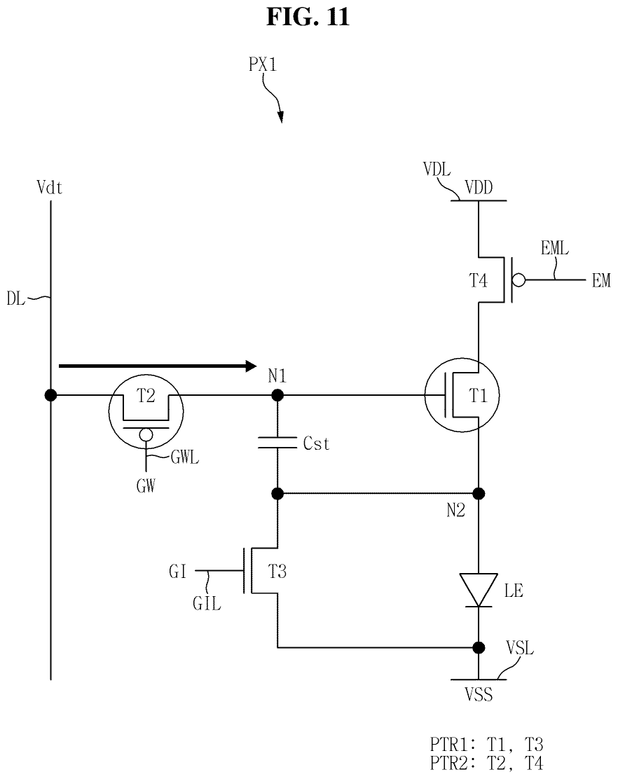

The operation of the display device 10 in the data write period P3 will be described with reference to FIGS. 8 and 11.

FIG. 11 is a diagram illustrating an operation of the display device 10 of FIG. 3 during a data write period P3 of FIG. 8.

In the data write period P3, the write scan signal GW having the active level may be applied to the gate electrode of the second transistor T2 through the write scan line GWL. Accordingly, in the data write period P3, the second transistor T2 may be turned on.

In the data write period P3, the initialization scan signal GI having the non-active level may be applied to the gate electrode of the third transistor T3 through the initialization scan line GIL. Accordingly, in the data write period P3, the third transistor T3 may be turned off.

In the data write period P3, the emission control signal EM having the non-active level may be applied to the gate electrode of the fourth transistor T4 through the emission control line EML. Accordingly, in the data write period P3, the fourth transistor T4 may be turned off.

In the data write period P3, the data voltage Vdt from the data line DL may be applied to the first node N1 through the turned-on second transistor T2. Accordingly, the first transistor T1 connected to the first node N1 through the gate electrode may be turned on. For example, in the data write period P3, the first transistor T1 may be turned on by a difference voltage (e.g., a gate-drain voltage) between the data voltage Vdt at the first node N1 and the voltage Vref-Vth at the second node N2.

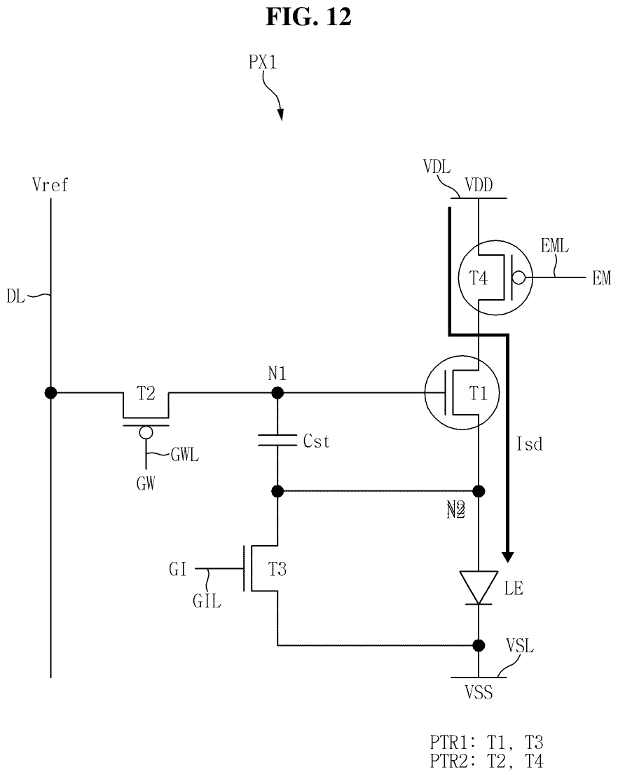

The operation of the display device 10 in the emission period P4 will be described with reference to FIGS. 8 and 12.

FIG. 12 is a diagram illustrating an operation of the display device 10 of FIG. 3 during an emission period P4 of FIG. 8.

In the emission period P4, the emission control signal EM having the active level may be applied to the gate electrode of the fourth transistor T4 through the emission control line EML. Accordingly, in the emission period P4, the fourth transistor T4 may be turned on.

In the emission period P4, the write scan signal GW having the non-active level may be applied to the gate electrode of the second transistor T2 through the write scan line GWL. Accordingly, in the emission period P4, the second transistor T2 may be turned off.

In the emission period P4, the initialization scan signal GI having the non-active level may be applied to the gate electrode of the third transistor T3 through the initialization scan line GIL. Accordingly, in the emission period P4, the third transistor T3 may be turned off.

In the emission period P4, the first transistor T1 may be maintained in a turn-on state by the gate-drain voltage maintained by the capacitor Cst. The gate-drain voltage may include the threshold voltage of the first transistor T1 and the data voltage Vdt.

In the emission period P4, as each of the first transistor T1 and the fourth transistor T4 are turned on, a driving current Isd from the driving voltage line VDL may be supplied to the light emitting element LE. Accordingly, the light emitting element LE may emit light according to the driving current Isd. At this time, since the gate-drain voltage maintained by the capacitor Cst includes the threshold voltage of the first transistor T1, the magnitude of the driving current Isd flowing to the light emitting element LE through the turned-on first transistor T1 may be determined based on the data voltage Vdt and the threshold voltage of the first transistor T1. Accordingly, the driving current Isd supplied to the light emitting element LE may accurately reflect the magnitude of the data voltage Vdt. In other words, the driving current Isd may have an accurate value in which the threshold voltage of the first transistor T1 is compensated.

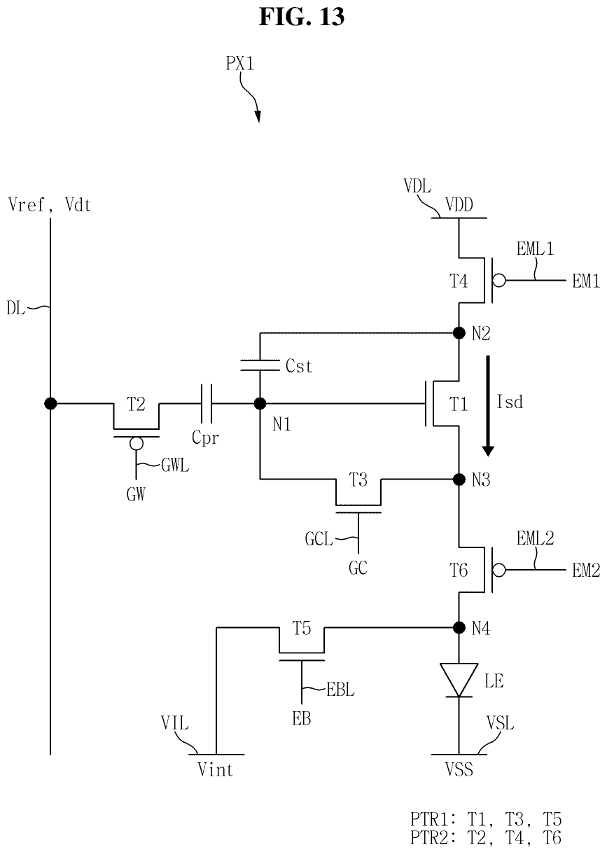

FIG. 13 is an equivalent circuit illustrating the first pixel PX1 according to an embodiment.

Referring to FIG. 13, the first pixel PX1 may be connected to the write scan line GWL, the compensation scan line GCL, a first emission control line EML1, a bias scan line EBL, a second emission control line EML2, and the data line DL. Further, the first pixel PX1 may be connected to the common voltage line VSL to which the common voltage VSS corresponding to a low potential voltage is applied, the driving voltage line VDL to which the driving voltage VDD corresponding to a high potential voltage is applied.

The first pixel PX1 may include the first pixel transistor PTR1, the second pixel transistor PTR2, a first capacitor Cpr, a second capacitor Cst, and the light emitting element LE. Here, the first pixel transistor PTR1 may include the first transistor T1, the third transistor T3 and a fifth transistor T5, and the second pixel transistor PTR2 may include the second transistor T2, the fourth transistor T4 and a sixth transistor T6.

The light emitting element LE emits light in response to the driving current Isd flowing through the channel of the first transistor T1. The emission amount of the light emitting element LE may be proportional to the driving current Isd. The light emitting element LE may be connected between a fourth node N4 and the common voltage line VSL. The first electrode of the light emitting element LE may be connected to the fourth node N4, and the second electrode thereof may be connected to the common voltage line VSL. The first electrode of the light emitting element LE may be an anode electrode, and the second electrode of the light emitting element LE may be a cathode electrode.

The first transistor T1 may be a driving transistor that controls a driving current flowing between the source electrode and the drain electrode thereof according to a voltage applied to the gate electrode thereof. The first transistor T1 may include a gate electrode connected to the first node N1, a source electrode connected to the second node N2, and a drain electrode connected to a third node N3. The first transistor T1 may be an N-type transistor.

The second transistor T2 may be connected between the data line DL and a first electrode of the first capacitor Cpr. The second transistor T2 may be turned on by the write scan signal GW of the write scan line GWL to connect the data line DL to the first electrode of the first capacitor Cpr. The second transistor T2 may include a gate electrode connected to the write scan line GWL, a source electrode connected to the data line DL, and a drain electrode connected to the first electrode of the first capacitor Cpr. The second transistor T2 may be a P-type transistor. The reference voltage Vref and the data voltage Vdt may be applied to the data line DL.

The third transistor T3 may be connected between the first node N1 and the third node N3. The third transistor T3 may be turned on by a compensation scan signal GC of the compensation scan line GCL to connect the first node N1 and the third node N3 to each other. The third transistor T3 may include a gate electrode connected to the compensation scan line GCL, a source electrode connected to the third node N3, and a drain electrode connected to the first node N1. The third transistor T3 may be an N-type transistor.

The fourth transistor T4 may be connected between the driving voltage line VDL and the second node N2. The fourth transistor T4 may be turned on by a first emission control signal EM1 of the first emission control line EML1 to connect the driving voltage line VDL and the second node N2 to each other. The fourth transistor T4 may include a gate electrode connected to the first emission control line EML1, a source electrode connected to the driving voltage line VDL, and a drain electrode connected to the first node N1. The fourth transistor T4 may be a P-type transistor.

The fifth transistor T5 may be connected between the fourth node N4 and the initialization voltage line VIL. The fifth transistor T5 may be turned on by a bias scan signal EB of the bias scan line EBL to connect the fourth node N4 and the initialization voltage line VIL. The fifth transistor T5 may include a gate electrode connected to the bias scan line EBL, a drain electrode connected to the fourth node N4, and a source electrode connected to the initialization voltage line VIL. The fifth transistor T5 may be an N-type transistor.

The sixth transistor T6 may be connected between the third node N3 and the fourth node N4. The sixth transistor T6 may be turned on by a second emission control signal EM2 of the second emission control line EML2 to connect the third node N3 and the fourth node N4 to each other. The sixth transistor T6 may include a gate electrode connected to the second emission control line EML2, a source electrode connected to the fourth node N3, and a drain electrode connected to the third node N3. The sixth transistor T6 may be a P-type transistor.

The first capacitor Cpr may be connected between the drain electrode of the second transistor T2 and the first node N1. The first electrode of the first capacitor Cpr may be connected to the drain electrode of the second transistor T2, and the second electrode of the first capacitor Cpr may be connected to the first node N1.

The second capacitor Cst may be connected between the first node N1 and the second node N2. The first electrode of the second capacitor Cst may be connected to the first node N1, and the second electrode of the second capacitor Cst may be connected to the second node N2.

At least one of the first to sixth transistors T1 to T6 may be a metal-oxide-semiconductor field effect transistor (MOSFET). For example, the second transistor T2, the fourth transistor T4, and the sixth transistor T6 corresponding to the second pixel transistor PTR2 may each be a P-type MOSFET. The second transistor T2, the fourth transistor T4, and the sixth transistor T6 may be disposed in the semiconductor backplane SBP, similar to the second pixel transistor PTR2 of FIG. 7 described above. For example, each of the second transistor T2, the fourth transistor T4, and the sixth transistor T6 may have the same configuration as the second pixel transistor PTR2 of FIG. 7.

At least one of the first to sixth transistors T1 to T6 described above may be an oxide-based transistor (e.g., an oxide semiconductor transistor). For example, each of the first transistor T1, the third transistor T3, and the fifth transistor T5 corresponding to the first pixel transistor PTR1 may be an N-type oxide-based transistor. The first transistor T1, the third transistor T3, and the fifth transistor T5 may be disposed in the light emitting element backplane EBP, similar to the first pixel transistor PTR1 of FIG. 7 described above. For example, each of the first transistor T1, the third transistor T3, and the fifth transistor T5 may have the same configuration as the first pixel transistor PTR1 of FIG. 7.

Although FIG. 13 illustrates that the first pixel PX1 includes the six transistors T1 to T6 and the two capacitors Cpr and Cst, the equivalent circuit of the first pixel PX1 is not limited to the example shown in FIG. 13. For example, the number of the transistors and the number of the capacitors of the first pixel PX1 may be changed in various ways.

In addition, the equivalent circuit of the second pixel PX2 and the equivalent circuit of the third pixel PX3 may be substantially the same as the equivalent circuit of the first pixel PX1 described in conjunction with FIG. 13. Thus, in the present disclosure, description of the equivalent circuits of the second pixel PX2 and the third pixel PX3 will be omitted.

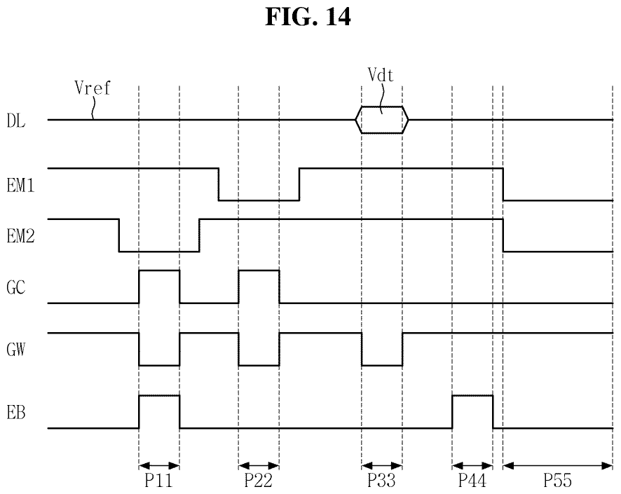

FIG. 14 is a diagram illustrating a timing of the reference voltage Vref, the data voltage Vdt, the first emission control signal EM1, the second emission control signal EM2, the compensation scan signal GC, the write scan signal GW, and the bias scan signal EB shown in FIG. 13.

The first pixel PX1 may be driven separately for each of an initialization period P11, a threshold voltage detection period P22, a data write period P33, a reset period P44, and an emission period P55.

The first emission control signal EM1, the second emission control signal EM2, the compensation scan signal GC, the write scan signal GW, and the bias scan signal EB may have an active level or a non-active level for each of the above-mentioned periods P11, P22, P33, P44, and P55. Here, the active level of each signal EM1, EM2, GC, GW, EB described above may mean a voltage level capable of turning on a corresponding transistor to which the corresponding signal is applied. In other words, the active level signal may have a value greater than the threshold voltage of the corresponding transistor. For example, as shown in FIG. 13, when each of the second transistor T2, the fourth transistor T4, and the sixth transistor T6 is a P-type transistor, the active level of each of the write scan signal GW, the first emission control signal EM1, and the second emission control signal EM2 may mean a low level (e.g., a negative polarity level or a low voltage level). For example, when each of the third transistor T3 and the fifth transistor T5 is an N-type transistor, the active level of each of the compensation scan signal GC and the bias scan signal EB may mean a high level (e.g., a positive polarity level or a high voltage level).

The non-active level of each signal EM1, EM2, GC, GW, EB may mean a voltage level which turns off a corresponding transistor. In other words, the non-active level signal may have a smaller value than the threshold voltage of the corresponding transistor. For example, as shown in FIG. 13, when each of the second transistor T2, the fourth transistor T4, and the sixth transistor T6 is a P-type transistor, the non-active level of each of the write scan signal GW, the first emission control signal EM1, and the second emission control signal EM2 may mean a high level (e.g., a positive polarity level or a high voltage level). For example, when each of the third transistor T3 and the fifth transistor T5 is an N-type transistor, the non-active level of each of the compensation scan signal GC and the bias scan signal EB may mean a low level (e.g., a negative polarity level or a low voltage level).

In the initialization period P11, the write scan signal GW, each of the compensation scan signal GC, the second emission control signal EM2, and the bias scan signal EB may have an active level, while the first emission control signal EM1 may have a non-active level. Further, in the initialization period P11, the reference voltage Vref may be applied to the data line DL.

In the threshold voltage detection period P22, each of the write scan signal GW, the compensation scan signal GC, and the first emission control signal EM1 may have an active level, while the bias scan signal EB and the second emission control signal EM2 may have a non-active level. Further, in the threshold voltage detection period P22, the reference voltage Vref may be applied to the data line DL.

In the data write period P33, the write scan signal GW may have an active level, while each of the compensation scan signal GC, the first emission control signal EM1, the bias scan signal EB, and the second emission control signal EM2 may have a non-active level. Further, in the data write period P33, the data voltage Vdt may be applied to the data line DL.

In the reset period P44, the bias scan signal EB may have an active level, while the write scan signal GW, the compensation scan signal GC, the first emission control signal EM1, and the second emission control signal EM2 may have a non-active level. Further, in the reset period P44, the reference voltage Vref may be applied to the data line DL.

In the emission period P55, each of the first emission control signal EM1 and the second emission control signal EM2 may have an active level, while the write scan signal GW, the compensation scan signal GC, and the bias scan signal EB may have a non-active level. Further, in the emission period P55, the reference voltage Vref may be applied to the data line DL.

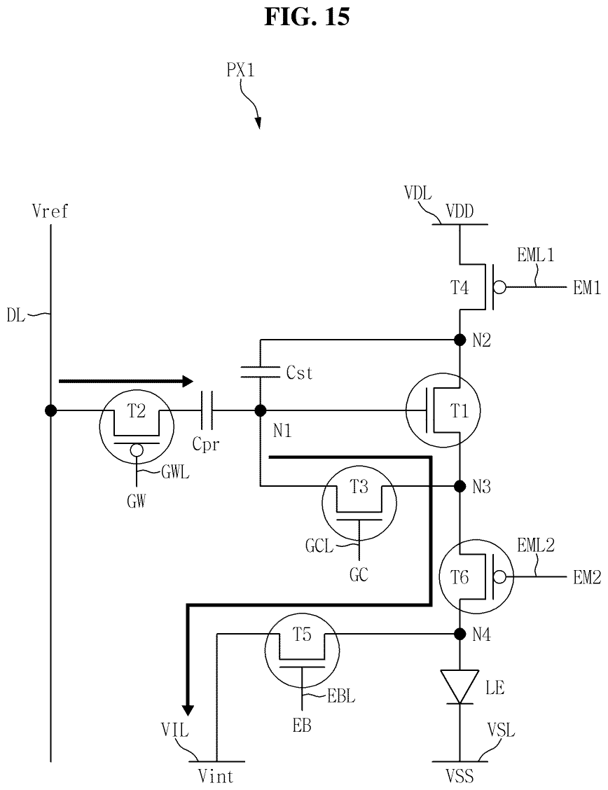

Hereinafter, the operation of the display device 10 will be described with reference to FIGS. 14 to 19 as follows. In FIGS. 15 to 19, the transistor surrounded by a circle means a turned-on transistor.

First, the operation of the display device 10 in the initialization period P11 will be described with reference to FIGS. 14 and 15.

FIG. 15 is a diagram illustrating an operation of the display device 10 of FIG. 13 during an initialization period P11 of FIG. 14.

In the initialization period P11, the write scan signal GW having the active level may be applied to the gate electrode of the second transistor T2 through the write scan line GWL. Accordingly, in the initialization period P11, the second transistor T2 may be turned on.

In the initialization period P11, the compensation scan signal GC having the active level may be applied to the gate electrode of the third transistor T3 through the compensation scan line GCL. Accordingly, in the initialization period P11, the third transistor T3 may be turned on.

In the initialization period P11, the bias scan signal EB having the active level may be applied to the gate electrode of the fifth transistor T5 through the bias scan line EBL. Accordingly, in the initialization period P11, the fifth transistor T5 may be turned on.

In the initialization period P11, the second emission control signal EM2 having the active level may be applied to the gate electrode of the sixth transistor T6 through the second emission control line EML2. Accordingly, in the initialization period P11, the sixth transistor T6 may be turned on.

In the initialization period P11, the first emission control signal EM1 having the non-active level may be applied to the gate electrode of the fourth transistor T4 through the first emission control line EML1. Accordingly, in the initialization period P11, the fourth transistor T4 may be turned off.

In the initialization period P11, the reference voltage Vref from the data line DL may be applied to the first electrode of the first capacitor Cpr through the turned-on second transistor T2, and the initialization voltage Vint from the initialization voltage line VIL may be applied to the first node N1, the third node N3, and the fourth node N4 through the turned-on third transistor T3, the turned-on fifth transistor T5, and the turned-on sixth transistor T6. Accordingly, the voltage of each of the gate electrode of the first transistor T1, the voltage of the drain electrode of the first transistor T1, the voltage of the first electrode of the first capacitor Cpr, the voltage of the second electrode of the first capacitor Cpr, the voltage of the first electrode of the second capacitor Cst, and the voltage of the anode electrode of the light emitting element LE may be initialized.

In the initialization period P11, the first transistor T1 may be turned on by the voltage at the first node N1 and the voltage at the third node N3. The initialization voltage Vint from the initialization voltage line VIL may be applied to the second node N2 through the turned-on first transistor T1. Therefore, in the initialization period P11, the voltage at the second node N2 may be initialized.

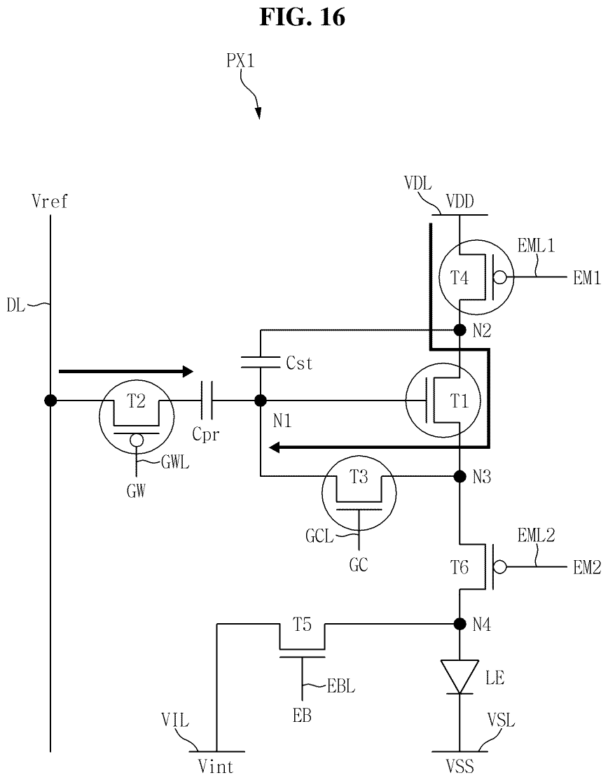

The operation of the display device 10 in the threshold voltage detection period P22 will be described with reference to FIGS. 14 and 16 as follows.

FIG. 16 is a diagram illustrating an operation of the display device 10 of FIG. 13 during a threshold voltage detection period P22 of FIG. 14.

In the threshold voltage detection period P22, the write scan signal GW having the active level may be applied to the gate electrode of the second transistor T2 through the write scan line GWL. Accordingly, in the threshold voltage detection period P22, the second transistor T2 may be turned on.

In the threshold voltage detection period P22, the compensation scan signal GC having the active level may be applied to the gate electrode of the third transistor T3 through the compensation scan line GCL. Accordingly, in the threshold voltage detection period P22, the third transistor T3 may be turned on.

In the threshold voltage detection period P22, the first emission control signal EM1 having the active level may be applied to the gate electrode of the fourth transistor T4 through the first emission control line EML1. Accordingly, in the threshold voltage detection period P22, the fourth transistor T4 may be turned on.

In the threshold voltage detection period P22, the bias scan signal EB having the non-active level may be applied to the gate electrode of the fifth transistor T5 through the bias scan line EBL. Accordingly, in the threshold voltage detection period P22, the fifth transistor T5 may be turned off.

In the threshold voltage detection period P22, the second emission control signal EM2 having the non-active level may be applied to the gate electrode of the sixth transistor T6 through the second emission control line EML2. Accordingly, in the threshold voltage detection period P22, the sixth transistor T6 may be turned off.

In the threshold voltage detection period P22, the first transistor T1 may be maintained in a turn-on state by the voltage applied to the first node N1 and the voltage applied to the third node N3 in the previous period (e.g., the initialization period P11).

In the threshold voltage detection period P22, the voltage at the second node N2 may be gradually increased by a current flowing through the turned-on fourth transistor T4 and the turned-on first transistor T1. In other words, as the sixth transistor T6 is turned off, the supply of the initialization voltage Vint to the third node N3 may be stopped, and accordingly, the voltage at the third node N3 may be gradually increased by a current flowing from the driving voltage line VDL through the turned-on fourth transistor T4 and the turned-on first transistor T1. The first node N1 and the third node N3 may be electrically connected to each other by the turned-on third transistor T3 in the threshold voltage detection period P22, but the voltage at the first node N1 does not change as much as the voltage at the third node N3 due to the coupling operation of the first capacitor Cpr and the second capacitor Cst. Accordingly, a voltage (e.g., a gate-drain voltage) between the gate electrode and the drain electrode of the first transistor T1 may be gradually decreased, and when the gate-drain voltage reaches the threshold voltage of the first transistor T1, the first transistor T1 may be turned off. At this time, the threshold voltage of the first transistor T1 may be detected and the detected threshold voltage of the first transistor T1 may be reflected in the first node N1. The threshold voltage of the first transistor T1 reflected in the first node N1 may be maintained by the second capacitor Cst.

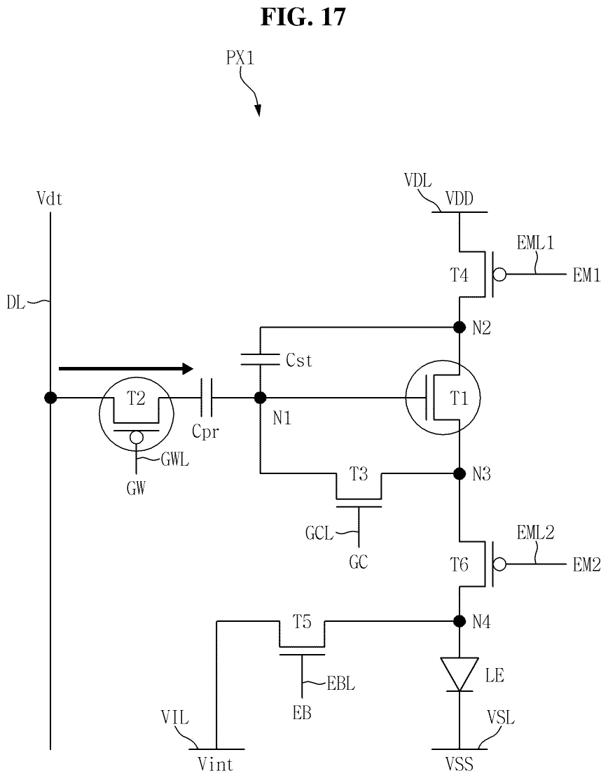

The operation of the display device 10 in the data write period P33 will be described with reference to FIGS. 14 and 17.

FIG. 17 is a diagram illustrating an operation of the display device 10 of FIG. 13 during a data write period P33 of FIG. 14.

In the data write period P33, the write scan signal GW having the active level may be applied to the gate electrode of the second transistor T2 through the write scan line GWL. Accordingly, in the data write period P33, the second transistor T2 may be turned on.

In the data write period P33, the compensation scan signal GC having the non-active level may be applied to the gate electrode of the third transistor T3 through the compensation scan line GCL. Accordingly, in the data write period P33, the third transistor T3 may be turned off.

In the data write period P33, the first emission control signal EM1 having the non-active level may be applied to the gate electrode of the fourth transistor T4 through the first emission control line EML1. Accordingly, in the data write period P33, the fourth transistor T4 may be turned off.

In the data write period P33, the bias scan signal EB having the non-active level may be applied to the gate electrode of the fifth transistor T5 through the bias scan line EBL. Accordingly, in the data write period P33, the fifth transistor T5 may be turned off.

In the data write period P33, the second emission control signal EM2 having the non-active level may be applied to the gate electrode of the sixth transistor T6 through the second emission control line EML2. Accordingly, in the data write period P33, the sixth transistor T6 may be turned off.

In the data write period P33, the data voltage Vdt from the data line DL may be applied to the first electrode of the first capacitor Cpr through the turned-on second transistor T2, and the data voltage Vdt applied to the first electrode of the first capacitor Cpr may be reflected in the first node N1 (e.g., the first node N1 in a floating state) by the coupling operation of the first capacitor Cpr. Accordingly, the first transistor T1 connected to the first node N1 through the gate electrode may be turned on.

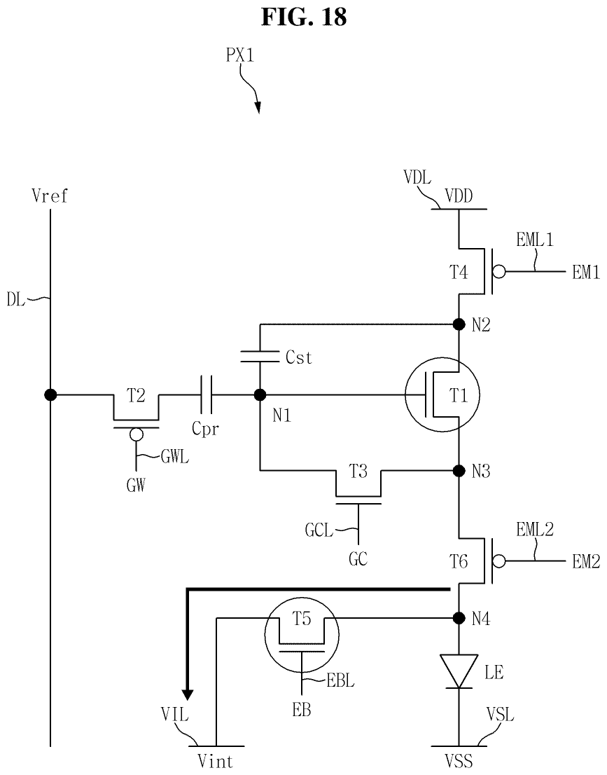

The operation of the display device 10 in the reset period P44 will be described with reference to FIGS. 14 and 18.

FIG. 18 is a diagram illustrating an operation of the display device 10 of FIG. 13 during a reset period P44 of FIG. 14.

In the reset period P44, the bias scan signal EB having the active level may be applied to the gate electrode of the fifth transistor T5 through the bias scan line EBL. Accordingly, in the reset period P44, the fifth transistor T5 may be turned on.

In the reset period P44, the write scan signal GW having the non-active level may be applied to the gate electrode of the second transistor T2 through the write scan line GWL. Accordingly, in the reset period P44, the second transistor T2 may be turned off.

In the reset period P44, the compensation scan signal GC having the non-active level may be applied to the gate electrode of the third transistor T3 through the compensation scan line GCL. Accordingly, in the reset period P44, the third transistor T3 may be turned off.

In the reset period P44, the first emission control signal EM1 having the non-active level may be applied to the gate electrode of the fourth transistor T4 through the first emission control line EML1. Accordingly, in the reset period P44, the fourth transistor T4 may be turned off.

In the reset period P44, the second emission control signal EM2 having the non-active level may be applied to the gate electrode of the sixth transistor T6 through the second emission control line EML2. Accordingly, in the reset period P44, the sixth transistor T6 may be turned off.

In the reset period P44, the initialization voltage Vint from the initialization voltage line VIL may be applied to the fourth node N4 through the turned-on fifth transistor T5. Accordingly, in the reset period, the voltage at the fourth node N4 may be initialized.

In the reset period, the first transistor T1 may be maintained in a turn-on state.

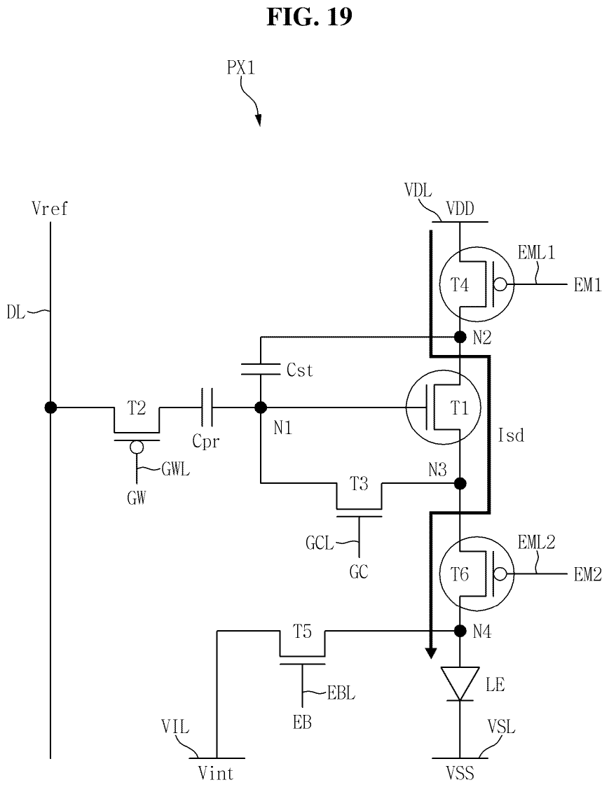

The operation of the display device 10 in the emission period P55 will be described with reference to FIGS. 14 and 19.

FIG. 19 is a diagram illustrating an operation of the display device 10 of FIG. 13 during an emission period P55 of FIG. 14.

In the emission period P55, the first emission control signal EM1 having the active level may be applied to the gate electrode of the fourth transistor T4 through the first emission control line EML1. Accordingly, in the emission period P55, the fourth transistor T4 may be turned on.

In the emission period P55, the second emission control signal EM2 having the active level may be applied to the gate electrode of the sixth transistor T6 through the second emission control line EML2. Accordingly, in the emission period P55, the sixth transistor T6 may be turned on.

In the emission period P55, the write scan signal GW having the non-active level may be applied to the gate electrode of the second transistor T2 through the write scan line GWL. Accordingly, in the emission period P55, the second transistor T2 may be turned off.

In the emission period P55, the compensation scan signal GC having the non-active level may be applied to the gate electrode of the third transistor T3 through the compensation scan line GCL. Accordingly, in the emission period P55, the third transistor T3 may be turned off.

In the emission period P55, the bias scan signal EB having the non-active level may be applied to the gate electrode of the fifth transistor T5 through the bias scan line EBL. Accordingly, in the emission period P55, the fifth transistor T5 may be turned off.

In the emission period P55, the first transistor T1 may be maintained in a turn-on state by the gate-source voltage maintained by the second capacitor Cst. The gate-source voltage may include the threshold voltage of the first transistor T1 and the data voltage Vdt.

In the emission period P55, as the fourth transistor T4, the first transistor T1, and the sixth transistor T6 are turned on, the driving current Isd from the driving voltage line VDL may be supplied to the light emitting element LE. Accordingly, the light emitting element LE may emit light according to the driving current Isd. At this time, since the gate-source voltage maintained by the second capacitor Cst includes the threshold voltage of the first transistor T1, the magnitude of the driving current Isd flowing to the light emitting element LE through the turned-on first transistor T1 may be determined based on the data voltage Vdt and the threshold voltage of the first transistor T1. Accordingly, the driving current Isd supplied to the light emitting element LE may accurately reflect the magnitude of the data voltage Vdt. In other words, the driving current Isd may have an accurate value in which the threshold voltage of the first transistor T1 is compensated.

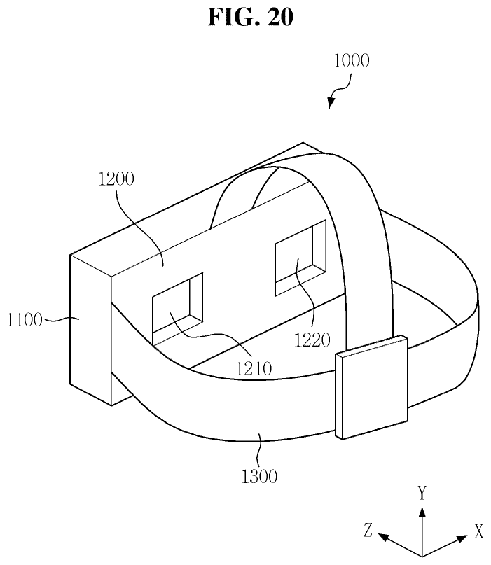

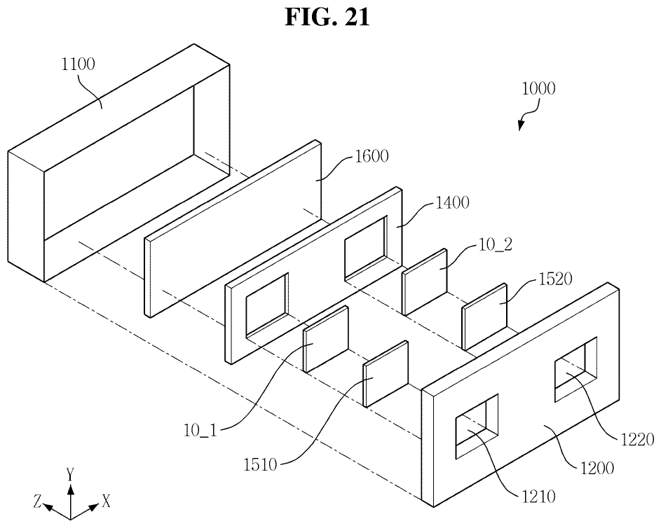

FIG. 20 is a perspective view illustrating a head mounted display according to an embodiment. FIG. 21 is an exploded perspective view illustrating an example of the head mounted display of FIG. 20.

Referring to FIGS. 20 and 21, a head mounted display 1000 according to an embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 to 19, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source input from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. The control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover an open surface of the display device housing 1100. The housing cover 1200 may include the first eyepiece 1210 at which the user's left eye is disposed and the second eyepiece 1220 at which the user's right eye is disposed. FIGS. 20 and 21 illustrate that the first eyepiece 1210 and the second eyepiece 1220 are disposed separately, but the embodiment of the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

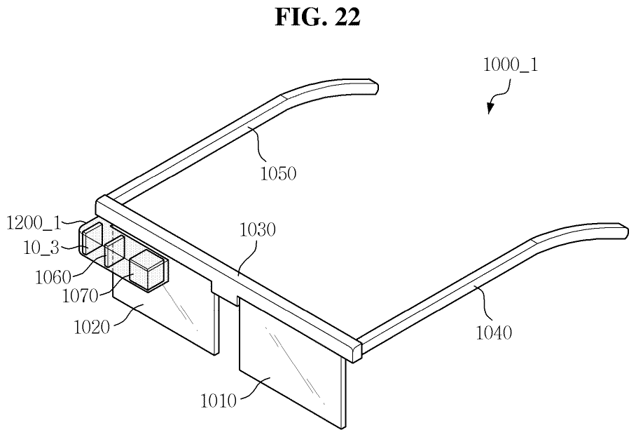

The head mounted band 1300 serves to secure the display device housing 1100 to the user's head such that the first eyepiece 1210 and the second eyepiece 1220 of the housing cover 1200 remain disposed on the user's left and right eyes, respectively. When the display device housing 1200 is implemented to be lightweight and compact, the head mounted display 1000 may be provided with an eyeglass frame as shown in FIG. 22 instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 22 is a perspective view illustrating a head mounted display according to an embodiment.

Referring to FIG. 22, a head mounted display 1000_1 according to an embodiment may be an eyeglasses-type display device in which a display device housing 1200_1 is implemented in a lightweight and compact manner. The head mounted display 1000_1 according to an embodiment may include a display device 10_3, a left eye lens 1010, a right eye lens 1020, a support frame 1030, eyeglass temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 22 illustrates that the display device housing 1200_1 is disposed at the right end of the support frame 1030, but the embodiment of the present disclosure is not limited thereto. For example, the display device housing 1200_1 may be disposed at the left end of the support frame 1030 to provide the image of the display device 10_3 to the user's left eye. The display device housing 1200_1 may be disposed at both the left and right ends of the support frame 1030 in order for the user to see the image displayed on the display device 10_3 through both the left and right eyes.

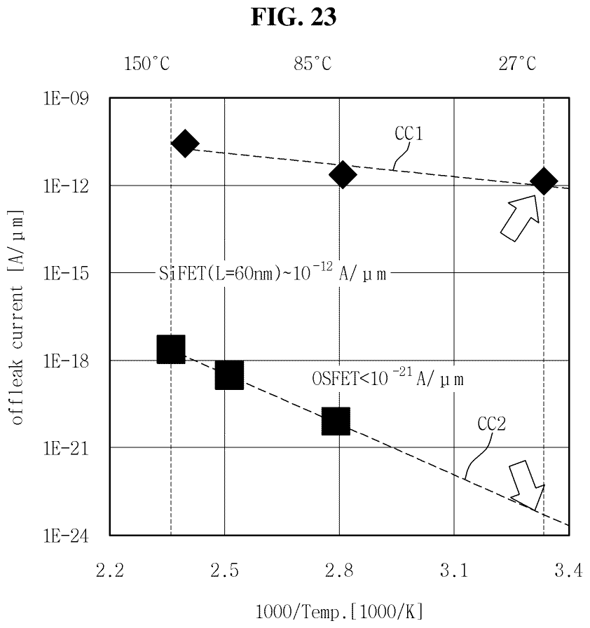

FIG. 23 is a graph illustrating the characteristics of off-leakage currents of a silicon transistor and an oxide transistor depending on temperature.

In FIG. 23, a first curve CC1 represents a characteristic curve of off-leakage current depending on the temperature for the silicon transistor including a silicon semiconductor, and a second curve CC2 represents a characteristic curve of off-leakage current depending on the temperature for the oxide transistor including an oxide semiconductor.

As shown in FIG. 23, the oxide transistor may have a significantly lower off-leakage current than the silicon transistor at a high temperature. Therefore, the display device 10 including a transistor (e.g., the first transistor T1 including an oxide semiconductor) according to an embodiment may have low power consumption and a high dynamic range. Accordingly, the display device 10 according to an embodiment may have improved power consumption and improved image quality.

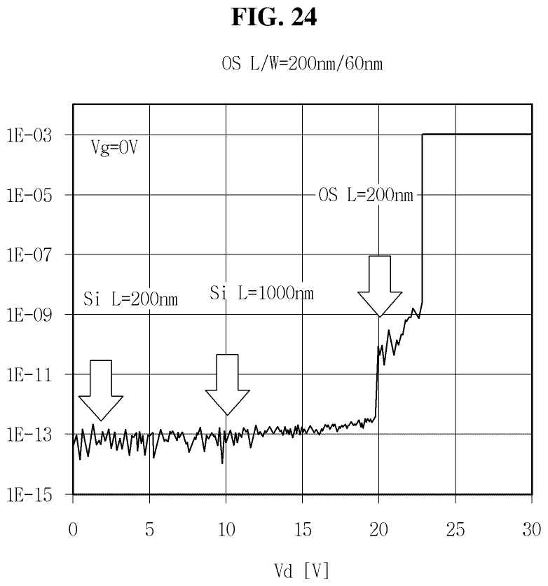

FIG. 24 is a graph illustrating the characteristics of driving current depending on drain voltages of a silicon transistor and an oxide transistor.

As shown in FIG. 24, the oxide transistor (OLL=200 nm) may have a high voltage tolerance that allows the driving current Id to be conducted with a stable magnitude even at a high drain voltage Vd of about 20 [V]. In other words, the oxide transistor may have a higher drain breakdown voltage than that of the silicon transistor (SiL=200 nm or SiL=1000 nm). Therefore, the display device 10 including a transistor (e.g., the first transistor T1 including an oxide semiconductor) according to an embodiment may have a high luminance, and thus it may be advantageously applied to an OLED display device having a tandem structure.

The display device according to the embodiment can be applied to various electronic devices. The electronic device according to one embodiment includes the display device described above and may further include modules or devices having additional functions in addition to the display device.

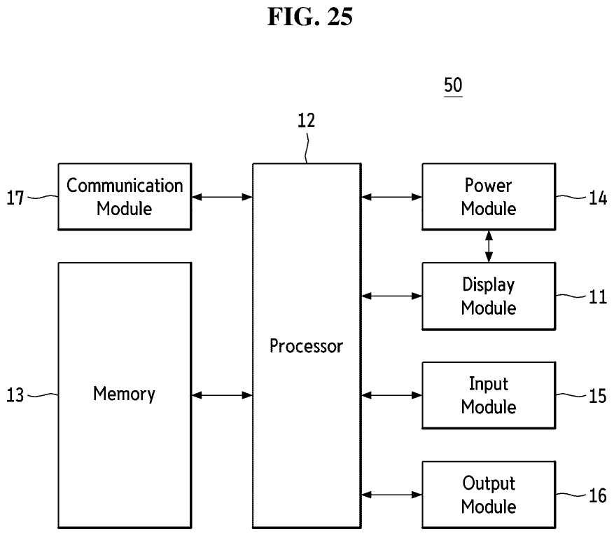

FIG. 25 is a block diagram of an electronic device according to one embodiment. Referring to FIG. 25, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

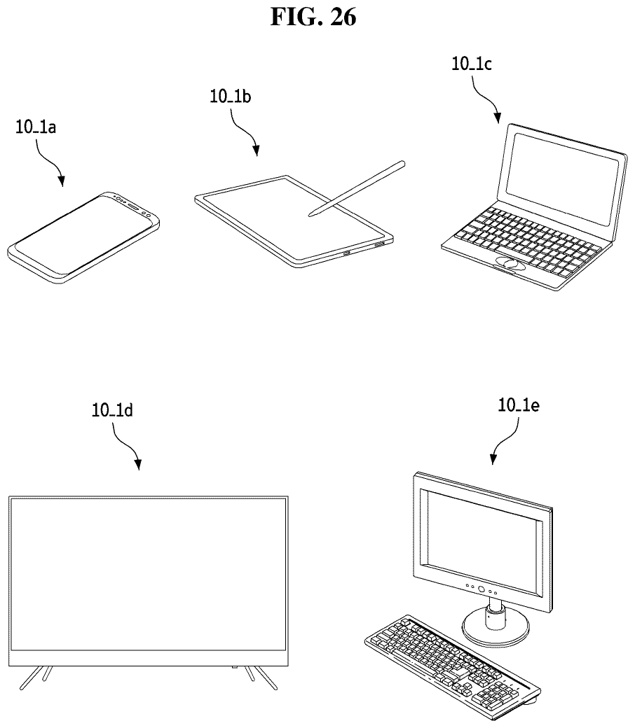

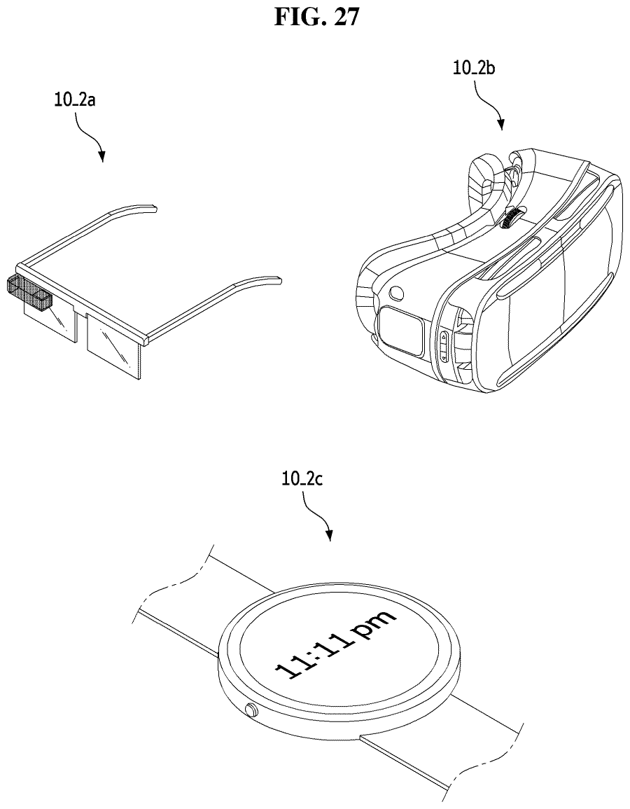

FIGS. 26, 27, and 28 are schematic diagrams of electronic devices according to various embodiments. FIGS. 26 to 28 illustrate examples of various electronic devices to which the display device according to the embodiments is applied.

FIG. 26 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

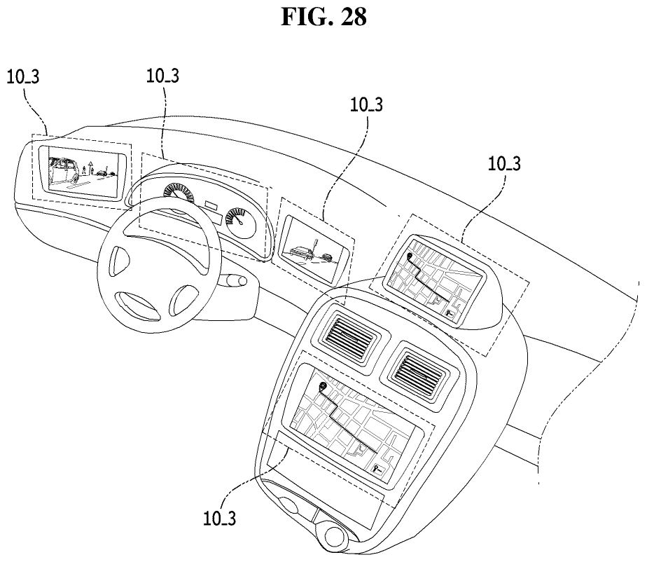

FIG. 28 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

The smart watch 10_2c includes a biometric sensor as an input device, and may provide biometric information recognized by the biometric sensor to the user through the display module. FIG. 29 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the embodiments of the present disclosure without substantially departing from the principles of the present disclosure. Therefore, the disclosed embodiments of the present disclosure are used in a generic and descriptive sense only and not for purposes of limitation.

What is claimed is:

1. A display device comprising:
a light emitting element;
a first transistor connected to the light emitting element;
a second transistor connected between a data line and the first transistor;
a third transistor connected between a gate electrode of the first transistor and a common voltage line;
a fourth transistor connected between a driving voltage line and the first transistor; and
a capacitor connected between the gate electrode of the first transistor and a drain electrode of the first transistor,
wherein at least one of the second transistor or the fourth transistor is a field effect transistor, and
at least one of the first transistor or the third transistor is an oxide semiconductor transistor.

2. The display device of claim 1, wherein the field effect transistor is a P-type transistor.

3. The display device of claim 1, wherein the oxide semiconductor transistor is an N-type transistor.

4. The display device of claim 1, further comprising a substrate on which the first to fourth transistors are disposed,
wherein at least one of the first transistor or the third transistor is disposed farther from the substrate than at least one of the second transistor or the fourth transistor.

5. The display device of claim 1, further comprising:
a write scan line connected to a gate electrode of the second transistor, and receiving a write scan signal;
an initialization scan line connected to a gate electrode of the third transistor, and receiving an initialization scan signal; and
an emission control line connected to a gate electrode of the fourth transistor, and receiving an emission control signal.

6. The display device of claim 5, wherein in an initialization period,
each of the initialization scan signal and the write scan signal has an active level,
the emission control signal has a non-active level, and
a reference voltage is applied to the data line.

7. The display device of claim 6, wherein in a threshold voltage detection period after the initialization period,
each of the emission control signal and the write scan signal has an active level,
the initialization scan signal has a non-active level, and
the reference voltage is applied to the data line.

8. The display device of claim 7, wherein in a data write period after the threshold voltage detection period,
the write scan signal has an active level,
each of the emission control signal and the initialization scan signal has a non-active level, and
a data voltage is applied to the data line.

9. The display device of claim 8, wherein in an emission period after the data write period,
the emission control signal has an active level,
each of the initialization scan signal and the write scan signal has a non-active level, and
the reference voltage is applied to the data line.

10. The display device of claim 1, wherein the field effect transistor is a metal-oxide-semiconductor field effect transistor (MOSFET).

11. The display device of claim 1, wherein the oxide semiconductor transistor contains indium-gallium-zinc oxide or indium-gallium-zinc-tin oxide.

12. A display device comprising:
a light emitting element;
a first transistor connected to the light emitting element;
a second transistor connected between a data line and the first transistor;
a third transistor connected between a gate electrode of the first transistor and a drain electrode of the first transistor;
a fourth transistor connected between a driving voltage line and the first transistor;
a fifth transistor connected between an initialization voltage line and an anode electrode of the light emitting element;
a sixth transistor connected between the first transistor and the anode electrode of the light emitting element;
a first capacitor connected between a drain electrode of the second transistor and the gate electrode of the first transistor; and
a second capacitor connected between the drain electrode of the second transistor and a source electrode of the first transistor,
wherein at least one of the second transistor, the fourth transistor, or the sixth transistor is a field effect transistor, and
at least one of the first transistor, the third transistor, or the fifth transistor is an oxide semiconductor transistor.

13. The display device of claim 12, wherein the field effect transistor is a P-type transistor.

14. The display device of claim 12, wherein the oxide semiconductor transistor is an N-type transistor.

15. The display device of claim 12, further comprising a substrate on which the first to sixth transistors are disposed,
wherein at least one of the first transistor, the third transistor, or the fifth transistor is disposed farther from the substrate than at least one of the second transistor, the fourth transistor, or the sixth transistor.

16. The display device of claim 12, further comprising:
a write scan line connected to a gate electrode of the second transistor, and receiving a write scan signal;
a compensation scan line connected to a gate electrode of the third transistor, and receiving a compensation scan signal;
a first emission control line connected to a gate electrode of the fourth transistor, and receiving a first emission control signal;
a bias scan line connected to a gate electrode of the fifth transistor, and receiving a bias scan signal; and
a second emission control line connected to a gate electrode of the sixth transistor, and receiving a second emission control signal.

17. The display device of claim 16, wherein in an initialization period,
each of the write scan signal, the compensation scan signal, the second emission control signal, and the bias scan signal has an active level,
the first emission control signal has a non-active level, and
a reference voltage is applied to the data line.

18. The display device of claim 17, wherein in a threshold voltage detection period after the initialization period,
each of the write scan signal, the compensation scan signal, and the first emission control signal has an active level,
each of the bias scan signal and the second emission control signal has a non-active level, and
the reference voltage is applied to the data line.

19. The display device of claim 18, in a data write period after the threshold voltage detection period,
the write scan signal has an active level,
each of the compensation scan signal, the first emission control signal, the bias scan signal, and the second emission control signal has a non-active level, and
a data voltage is applied to the data line.

20. The display device of claim 19, wherein in a reset period after the data write period,
the bias scan signal has an active level,
each of the write scan signal, the compensation scan signal, the first emission control signal, and the second emission control signal has a non-active level, and
the reference voltage is applied to the data line.

21. The display device of claim 20, wherein in an emission period after the reset period,
each of the first emission control signal and the second emission control signal has an active level,
each of the write scan signal, the compensation scan signal, and the bias scan signal has a non-active level, and
the reference voltage is applied to the data line.

22. An electronic device comprising:
a display device including a screen,
wherein the display device comprises:
a light emitting element;
a first transistor connected to the light emitting element;
a second transistor connected between a data line and the first transistor;
a third transistor connected between a gate electrode of the first transistor and a common voltage line;
a fourth transistor connected between a driving voltage line and the first transistor; and
a capacitor connected between the gate electrode of the first transistor and a drain electrode of the first transistor,
wherein at least one of the second transistor or the fourth transistor is a field effect transistor, and
at least one of the first transistor or the third transistor is an oxide semiconductor transistor.

23. The electronic device of claim 22, wherein the electronic device includes smartphones, tablets, laptops, televisions, desk monitors, smart glasses, smart watches, head-mounted displays and vehicles.
